(19) United States
(12) Patent Application Publication
(10) Pub. No.: US 2010/0258822 A1
(43) Pub. Date: Oct. 14, 2010

(54) SEMICONDUCTOR LIGHT-EMITTING DEVICE ASSEMBLY MANUFACTURING METHOD, SEMICONDUCTOR LIGHT-EMITTING DEVICE, ELECTRONIC DEVICE, AND IMAGE DISPLAY DEVICE

(75) Inventor: Arata Kobayashi, Kanagawa (JP)

Correspondence Address: K&L Gates LLP, P. O. BOX 1135, CHICAGO, IL, 60690, US

(73) Assignee: SONY CORPORATION, Tokyo (JP)

(21) Appl. No.: 12/749,978

(22) Filed: Mar. 30, 2010

(30) Foreign Application Priority Data
Apr. 8, 2009 (JP) P2009-093683

(51) Int. Cl. H01L 33/00; H01L 31/00

(52) U.S. Cl. 257/88; 257/103; 438/34; 257/E33.023; 257/E33.001; 257/E31.001

(57) ABSTRACT

A method of manufacturing a semiconductor light-emitting device assembly includes providing light-emitting device portions on a light-emitting device production substrate so as to be separated from each other, each of the light-emitting device portions including a laminated structure, in which a first compound semiconductor layer, an active layer, and a second compound semiconductor layer are sequentially laminated, and a second electrode provided on the second compound semiconductor layer; forming an insulating layer on an entire surface so as to have an opening portion in which a top central portion of the second electrode is exposed; providing an extraction electrode to each light-emitting device portion so as to be patterned to extend from a top surface of the second electrode to the insulating layer; and forming an adhesive layer so as to cover an entire surface and attaching a support substrate using the adhesive layer.

### CROSS REFERENCES TO RELATED APPLICATIONS

The present application claims priority to Japanese Priority Patent Application JP 2009-093683 filed in the Japan Patent Office on Apr. 8, 2009, the entire contents of which is hereby incorporated by reference.

### BACKGROUND

The present application relates to a semiconductor light-emitting device assembly manufacturing method, a semiconductor light-emitting device, an electronic device, and an image display device.

There are various electronic devices manufactured by mounting micro-devices on a substrate for display devices. An example of such electronic devices is a light-emitting diode display device. In such a light-emitting diode display device, a red light-emitting diode functions as a red light-emitting subpixel, a green light-emitting diode functions as a green light-emitting subpixel, and a blue light-emitting diode functions as a blue light-emitting subpixel. The light-emitting diode display device displays color images according to the emission states of the three types of subpixels.

The light-emitting diode display device generally includes a plurality of first wirings extending in a first direction, a plurality of second wirings extending in a second direction different from the first direction, and a plurality of light-emitting diodes each being connected to a first connection portion and a second connection portion. The light-emitting diodes are disposed in regions where the first wirings and the second wirings overlap each other. The first connection portion of each of the light-emitting diodes is connected to the first wiring, and the second connection portion of each of the light-emitting diodes is connected to the second wiring.

For example, in a 40-inch diagonal full HD (High Definition) full-color display, the number of pixels in a horizontal direction of a screen is 1920, and the number of pixels in a vertical direction of a screen is 1080. In this case, therefore, the number of the light-emitting diodes mounted is 1920×1080×(the number of the three types of light-emitting diodes, i.e., the red light-emitting diode, the green light-emitting diode, and the blue light-emitting diode, necessary for forming one pixel), that is, about 6,000,000. Therefore, a known step transfer method (step mounting method) is used as a method of mounting such a huge number of light-emitting diodes on a display substrate for displays having a nominal diagonal of 40 inches. In this step transfer method, light-emitting diodes are formed in an array such that the array has a size smaller than the screen size, and the light-emitting diodes are sequentially transferred from the light-emitting diode array to be mounted on the display substrate while the positions of the light-emitting diodes are adjusted. An example of the transfer method is described in JP-A-2004-273596 and JP-A-2004-281630, for example.

In general, a number of light-emitting diode portions 510A are formed in an array on a light-emitting device production substrate. Each of the light-emitting diode portions 510A is then moved (for example, transferred) from the light-emitting device production substrate to a display substrate. As shown in a schematic partial cross-sectional view of FIG. 29, each of the light-emitting device portions 510A that are formed on the light-emitting device production substrate includes a first compound semiconductor layer 511 of an n conductivity type, an active layer 513, and a second compound semiconductor layer 512 having a p-conductivity type, which are sequentially formed. Furthermore, a p-side electrode 515 is provided on the second compound semiconductor layer 512, and an n-side electrode is provided on the first compound semiconductor layer 511. The structure shown in FIG. 29 is a structure of a previous step before the n-side electrode is formed. Here, reference numeral 519 designates a light-emitting device production substrate, and reference numeral 520 designates a support substrate used for a step transfer method (step mounting method). Moreover, an insulating layer 517 is formed on a portion of the light-emitting device production substrate 519 disposed between the adjacent light-emitting device portions 510A, and an extraction electrode 516 is provided in each of the light-emitting device portions 510A so as to extend from a top surface of the p-side electrode 515 to the insulating layer 517. Furthermore, in order to achieve an electrical connection to a second wiring (not shown) in the step transfer method (step mounting method), a copper-plating layer 530 is formed on the extraction electrode 516. In addition, an adhesive layer 518 is formed on a portion of the insulating layer 517 disposed between the adjacent copper-plating layers 530 so as to achieve a bonding to the support substrate 520.

### SUMMARY

Here, in an upper portion of the insulating layer 517, the thickness of the copper-plating layer 530 is about 2 μm. Therefore, the adhesive layer 518 formed on the portion of the insulating layer 517 disposed between the adjacent copper-plating layers 530 also has a thickness of about 2 μm or more. When the support substrate 520 is bonded in such a state, the adhesive layer 518 is contracted with the curing of the adhesive layer 518, and thus stress occurs in the light-emitting device portion 510A (see the empty arrows in FIG. 29). As a result, characteristic deterioration such as an increased driving voltage or a decreased optical power may occur in the finally obtained light-emitting diodes.

Therefore, it is desirable to provide a semiconductor light-emitting device assembly manufacturing method, a semiconductor light-emitting device, an electronic device, and an image display device, in which stress hardly occurs in light-emitting device portions even when a light-emitting device production substrate having the light-emitting device portions constituting a semiconductor light-emitting device formed thereon is bonded to another substrate.

According to one embodiment, there is provided a method of manufacturing a semiconductor light-emitting device assembly, including:

(A) providing a plurality of light-emitting device portions on a light-emitting device production substrate so as to be separated from each other, each of the plurality of light-emitting device portions including a laminated structure, in which a first compound semiconductor layer having a first conductivity type, an active layer, and a second compound semiconductor layer having a second conductivity type different from the first conductivity type are sequentially laminated, and a second electrode provided on the second compound semiconductor layer;

(B) forming an insulating layer on an entire surface so as to have an opening portion in which a top central portion of the second electrode of each light-emitting device portion is exposed;

(C) providing an extraction electrode to each light-emitting device portion so as to be patterned to extend from a top surface of the second electrode exposed to a bottom portion of the opening portion to the insulating layer; and

(D) forming an adhesive layer so as to cover an entire surface and attaching a support substrate using the adhesive layer,

wherein in the step (D), the adhesive layer in which a portion of the extraction electrode is exposed is directly formed on the extraction electrode.

According to a first or second embodiment, there is provided a semiconductor light-emitting device including:

(a) a light-emitting device portion including a laminated structure, in which a first compound semiconductor layer having a first conductivity type, an active layer, and a second compound semiconductor layer having a second conductivity type different from the first conductivity type are sequentially laminated, and a second electrode provided on the second compound semiconductor layer;

(b) an insulating layer that covers a side surface of the light-emitting device portion and a top peripheral portion of the second compound semiconductor layer and has an opening portion in which a top central portion of the second electrode is exposed;

(c) an extraction electrode that is formed on the insulating layer so as to extend from the exposed top surface of the second electrode to the insulating layer; and

(d) a first electrode that is electrically connected to the first compound semiconductor layer,

In the semiconductor light-emitting device according to the first embodiment, a second insulating layer formed of an adhesive is directly formed on a portion of the extraction electrode, and the second insulating layer is not formed on the remaining portions of the extraction electrode.

In the semiconductor light-emitting device according to the second embodiment, a planar shape of the second compound semiconductor layer and a planar shape of the opening portion of the insulating layer are rectangular.

According to the first or second embodiment, there is provided an electronic device or an image display device including:

(A) a plurality of first wirings extending in a first direction;

(B) a plurality of second wirings extending in a second direction different from the first direction; and

(C) a plurality of semiconductor light-emitting devices each having a first connection portion and a second connection portion, the first connection portion being electrically connected to the first wirings, the second connection portion being electrically connected to the second wirings.

The semiconductor light-emitting devices each includes:

(a) a light-emitting device portion including a laminated structure, in which a first compound semiconductor layer having a first conductivity type, an active layer, and a second compound semiconductor layer having a second conductivity type different from the first conductivity type are sequentially laminated, and a second electrode provided on the second compound semiconductor layer;

(b) an insulating layer that covers a side surface of the light-emitting device portion and a top peripheral portion of the second compound semiconductor layer and has an opening portion in which a top central portion of the second electrode is exposed;

(c) an extraction electrode that is formed on the insulating layer so as to extend from the exposed top surface of the second electrode to the insulating layer; and

(d) a first electrode that is electrically connected to the first compound semiconductor layer, wherein:

the extraction electrode is electrically connected to the second connection portion or forms the second connection portion;

the first electrode is electrically connected to the first connection portion or forms the first connection portion.

In the electronic device or the image display device according to the first embodiment, a second insulating layer formed of an adhesive is directly formed on a portion of the extraction electrode but is not formed on the remaining portions of the extraction electrode.

In the electronic device or the image display device according to the second embodiment, a planar shape of the second compound semiconductor layer and a planar shape of the opening portion of the insulating layer are rectangular.

In the semiconductor light-emitting device assembly manufacturing method according to one embodiment, the semiconductor light-emitting device according to the first embodiment, the electronic device according to the first embodiment, or the image display device according to the first embodiment, basically, the second insulating layer (or the adhesive layer) formed of an adhesive is directly formed on a portion of the extraction electrode, and the second insulating layer (or the adhesive layer) is not formed on the remaining portions of the extraction electrode. Therefore, it is possible to reduce the amount of contraction during curing of the second insulating layer (or the adhesive layer). As a result, it is possible to achieve a reduction in stress occurring in the semiconductor light-emitting device or the light-emitting device portion when the light-emitting device production substrate having the light-emitting device portions constituting the semiconductor light-emitting device formed thereon is bonded to another substrate. Moreover, in the semiconductor light-emitting device according to the second embodiment, the electronic device according to the second embodiment, or the image display device according to the second embodiment, the planar shape of the second compound semiconductor layer and the planar shape of the opening portion of the insulating layer are rectangular. Therefore, it is possible to achieve a reduction in the area of the second insulating layer (or the adhesive layer) occupying the upper portion of the extraction electrode. As a result, it is possible to achieve a reduction in stress occurring in the semiconductor light-emitting device or the light-emitting device portion. Moreover, from the above-mentioned results, it is possible to certainly prevent occurrence of such a problem that characteristic deterioration such as an increased driving voltage or a decreased optical power occurs in the semiconductor light-emitting devices. Furthermore, since the second insulating layer (or the adhesive layer) formed of an adhesive is directly formed on a portion of the extraction electrode, and the second insulating layer (or the adhesive layer) is not formed on the remaining portions of the extraction electrode. Therefore, it is possible to maintain a high degree of flatness of the semiconductor light-emitting device or the light-emitting device portion, which leads to improved process reliability and improved reliability of the semiconductor light-emitting device or the light-emitting device portion. In addition, since the extraction electrode is electrically connected to the second connection portion or forms the second connection portion, it is not necessary to form a copper-plating layer particularly on the extraction electrode.

Additional features and advantages are described herein, and will be apparent from the following Detailed Description and the figures.

### BRIEF DESCRIPTION OF THE FIGURES

FIGS. 1A and 1B are schematic partial cross-sectional views of a semiconductor light-emitting device according to Example 1, in which FIG. 1A shows a state before a support substrate is bonded thereto, and FIG. 1B shows a state where the support substrate is bonded thereto.

FIG. 2 is a schematic diagram showing the arrangement of the outer edge of a top peripheral portion of a second compound semiconductor layer, a second electrode, and an opening portion provided to an insulating layer of the semiconductor light-emitting device according to Example 1.

FIG. 3 is a schematic diagram showing the shape of the outer edge of an extraction electrode of the semiconductor light-emitting device according to Example 1.

FIGS. 4A to 4C are schematic partial cross-sectional views of a light-emitting device production substrate and the like, showing a method of manufacturing a semiconductor light-emitting device assembly according to Example 1.

FIG. 5 is a schematic plan view of one light-emitting unit of a light-emitting diode display device according to Example 2.

FIGS. 6A, 6B, and 6C are schematic partial cross-sectional views of one light-emitting unit of the light-emitting diode display device according to Example 2, taken along the arrows A-A, B-B, and C-C in FIG. 5, respectively.

FIGS. 7A, 7B, and 7C are schematic partial cross-sectional views of one light-emitting unit of the light-emitting diode display device according to Example 2, taken along the arrows D-D, E-E, and F-F in FIG. 5, respectively.

FIGS. 8A, 8B, and 8C are schematic partial cross-sectional views of the light-emitting diode and the like, showing a method of manufacturing the light-emitting diode display device according to Example 2, in succession to FIG. 1B.

FIGS. 9A and 9B are schematic partial cross-sectional views of the light-emitting diode and the like, showing the method of manufacturing the light-emitting diode display device according to Example 2, in succession to FIG. 8C.

FIGS. 10A and 10B are schematic partial cross-sectional views of the light-emitting diode and the like, showing the method of manufacturing the light-emitting diode display device according to Example 2, in succession to FIG. 9B.

FIGS. 11A, 11B, and 11C are schematic partial cross-sectional views equivalent to those taken along the arrows B-B, E-E, and F-F in FIG. 5, respectively, showing the method of manufacturing the light-emitting diode display device according to Example 2.

FIGS. 12A, 12B, and 12C are schematic partial cross-sectional views equivalent to those taken along the arrows B-B, E-E, and F-F in FIG. 5, respectively, showing the method of manufacturing the light-emitting diode display device according to Example 2, in succession to FIGS. 11A, 11B, and 11C, respectively.

FIGS. 13A, 13B, and 13C are schematic partial cross-sectional views equivalent to those taken along the arrows B-B, E-E, and F-F in FIG. 5, respectively, showing the method of manufacturing the light-emitting diode display device according to Example 2, in succession to FIGS. 12A, 12B, and 12C, respectively.

FIGS. 14A, 14B, and 14C are schematic partial cross-sectional views equivalent to those taken along the arrows B-B, E-E, and F-F in FIG. 5, respectively, showing the method of manufacturing the light-emitting diode display device according to Example 2, in succession to FIGS. 13A, 13B, and 13C, respectively.

FIGS. 15A, 15B, and 15C are schematic partial cross-sectional views equivalent to those taken along the arrows B-B, E-E, and F-F in FIG. 5, respectively, showing the method of manufacturing the light-emitting diode display device according to Example 2, in succession to FIGS. 14A, 14B, and 14C, respectively.

FIGS. 16A, 16B, and 16C are schematic partial cross-sectional views equivalent to those taken along the arrows B-B, E-E, and F-F in FIG. 5, respectively, showing the method of manufacturing the light-emitting diode display device according to Example 2, in succession to FIGS. 15A, 15B, and 15C, respectively.

FIGS. 17A, 17B, and 17C are schematic partial cross-sectional views equivalent to those taken along the arrows B-B, E-E, and F-F in FIG. 5, respectively, showing the method of manufacturing the light-emitting diode display device according to Example 2, in succession to FIGS. 16A, 16B, and 16C, respectively.

FIGS. 18A, 18B, and 18C are schematic partial cross-sectional views equivalent to those taken along the arrows B-B, E-E, and F-F in FIG. 5, respectively, showing the method of manufacturing the light-emitting diode display device according to Example 2, in succession to FIGS. 17A, 17B, and 17C, respectively.

FIGS. 19A, 19B, and 19C are schematic partial cross-sectional views equivalent to those taken along the arrows B-B, E-E, and F-F in FIG. 5, respectively, showing the method of manufacturing the light-emitting diode display device according to Example 2, in succession to FIGS. 18A, 18B, and 18C, respectively.

FIGS. 20A, 20B, and 20C are schematic partial cross-sectional views equivalent to those taken along the arrows B-B, E-E, and F-F in FIG. 5, respectively, showing the method of manufacturing the light-emitting diode display device according to Example 2, in succession to FIGS. 19A, 19B, and 19C, respectively.

FIGS. 21A, 21B, and 21C are schematic partial cross-sectional views equivalent to those taken along the arrows A-A, B-B, and C-C in FIG. 5, respectively, showing one light-emitting unit of a light-emitting diode display device according to Example 3.

FIGS. 22A, 22B, and 22C are schematic partial cross-sectional views equivalent to those taken along the arrows D-D, E-E, and F-F in FIG. 5, respectively, showing one light-emitting unit of the light-emitting diode display device according to Example 3.

FIGS. 23A, 23B, and 23C are schematic partial cross-sectional views equivalent to those taken along the arrows B-B, E-E, and F-F in FIG. 5, respectively, showing a method of manufacturing the light-emitting diode display device according to Example 3.

FIGS. 24A, 24B, and 24C are schematic partial cross-sectional views equivalent to those taken along the arrows B-B, E-E, and F-F in FIG. 5, respectively, showing the method of manufacturing the light-emitting diode display device according to Example 3, in succession to FIGS. 23A, 23B, and 23C, respectively.

FIGS. 25A, 25B, and 25C are schematic partial cross-sectional views equivalent to those taken along the arrows B-B, E-E, and F-F in FIG. 5, respectively, showing the method of manufacturing the light-emitting diode display device according to Example 3, in succession to FIGS. 24A, 24B, and 24C, respectively.

FIG. 26 is a schematic plan view of one light-emitting unit according to a modified example of the light-emitting diode display device according to Example 2.

FIGS. 27A and 27B are schematic partial plan views showing the method of manufacturing the light-emitting diode display device according to Example 2.

FIGS. 28A and 28B are schematic partial plan views showing the method of manufacturing the light-emitting diode display device according to Example 2.

FIG. 29 is a schematic partial cross-sectional view of a light-emitting diode formed in a light-emitting device production substrate according to the related art.

### DETAILED DESCRIPTION

The present application will be described based on Examples by referring to the drawings according to an embodiment. However, the present application is not limited to Examples, and various numerical values and materials described in Examples are only examples. The description will be given in the following order:

1. Overall Description of Semiconductor Light-Emitting device Assembly Manufacturing Method of The Present Invention, Semiconductor Light-Emitting device according to The First and Second Embodiments, Electronic device according to The First and Second Embodiments, and Image Display Device according to The First and Second Embodiments;

2. Example 1 (Semiconductor Light-Emitting device according to The First and Second Embodiments and Semiconductor Light-Emitting device Assembly Manufacturing Method);

3. Example 2 (Electronic Device according to The First and Second Embodiments and Image Display Device according to The First and Second Embodiments); and

4. Example 3 (Modification of Example 2 and The Like)

In the semiconductor light-emitting device assembly manufacturing method according to the embodiment, a planar shape of the opening portion of the insulating layer formed in the step (B) may be rectangular. Here, it is preferable that the planar shape of the second compound semiconductor layer is also rectangular, and that the planar shape of the opening portion of the insulating layer is similar to the planar shape of the second compound semiconductor layer. Moreover, in the semiconductor light-emitting device according to the first embodiment, the planar shape of the second compound semiconductor layer and the planar shape of the opening portion of the insulating layer may be rectangular. Here, it is preferable that the planar shape of the opening portion of the insulating layer is similar to the planar shape of the second compound semiconductor layer. In the semiconductor light-emitting device according to the second embodiment, it is also preferable that the planar shape of the opening portion of the insulating layer is similar to the planar shape of the second compound semiconductor layer.

In the semiconductor light-emitting device assembly manufacturing method according to the embodiment including the above-mentioned preferred configuration, in the step (C), the patterned extraction electrode may be provided to each light-emitting device portion by forming an extraction electrode layer on the insulating layer so as to extend from the top surface of the second electrode exposed to the bottom portion of the opening portion by a physical vapor deposition method (PVD method), and then patterning the extraction electrode layer. Moreover, in this case, or/and in the semiconductor light-emitting device, the electronic device, and the image display device according to the first and second embodiments, it is preferable that an average thickness of the extraction electrode on the top surface of the second electrode is 0.1 μm to 1 μm.

In the semiconductor light-emitting device assembly manufacturing method according to the embodiment including the above-mentioned preferred configuration and structure, the semiconductor light-emitting device according to the first and second embodiments, the electronic device according to the first and second embodiments, and the image display device according to the first and second embodiments, it is preferable that the maximum thickness tmax of the adhesive layer (second insulating layer) on an outer peripheral portion of each light-emitting device portion or the semiconductor light-emitting device is 1.5 μm or less.

Furthermore, in the semiconductor light-emitting device assembly manufacturing method according to the embodiment including the above-mentioned preferred configuration and structure, the semiconductor light-emitting device according to the first and second embodiments, the electronic device according to the first and second embodiments, and the image display device according to the first and second embodiments (hereinafter, these will be sometimes collectively referred to simply as “present embodiments”), it is preferable that when it is assumed that as measured from a surface of the first compound semiconductor layer opposing a surface thereof being in contact with the active layer, the height of the thinnest portion of the insulating layer formed on a region of the light-emitting device production substrate disposed between the adjacent light-emitting device portions is H₀, and the height of the thickest portion of the insulating layer covering the outer peripheral portion of the second electrode is H₁, the value of (H₁−H₀) is 0.5 μm to 1.0 μm or less.

In the electronic device or the image display device according to the first and second embodiments, the extraction electrode is configured to be electrically connected to the second connection portion or is configured to form the second connection portion. Examples of the former configuration include a configuration such that an extension portion of the second connection portion is extended to the extraction electrode and a configuration such that the second connection portion and the extraction electrode are connected by a conductive material layer. In contrast, examples of the latter configuration include a configuration such that the extraction electrode itself serves as the second connection portion. On the other hand, the first electrode is configured to be electrically connected to the first connection portion or is configured to form the first connection portion. Examples of the former configuration include a configuration such that an extension portion of the first connection portion is extended to the first electrode and a configuration such that the first connection portion and the first electrode are connected by a conductive material layer. In contrast, examples of the latter configuration include a configuration such that the first electrode itself serves as the first connection portion.

In the electronic device or the image display device according to the first and second embodiments, the semiconductor light-emitting device may be a light-emitting diode (LED) and a semiconductor laser.

The size (for example, a chip size) of the semiconductor light-emitting device is not particularly limited. The semiconductor light-emitting device typically has a very small size. Specifically, the semiconductor light-emitting device has a size of, for example, 1 mm or less, 0.3 mm or less, or 0.1 mm or less, and more specifically 0.03 mm or less. The electronic device (or the image display device) includes a plurality of semiconductor light-emitting devices. The number, the type, the mounting (arrangement), and the pitch of the semiconductor light-emitting devices are determined in accordance with the application and the functions of the electronic device, the specification necessary for the electronic device or the image display device, and the like.

In the light-emitting diode display device according to the first and second embodiments, each of the plurality of first wirings has a strip shape as a whole and extends in the first direction. Each of the plurality of second wirings has a strip shape as a whole and extends in the second direction different from the first direction (for example, in a direction perpendicular to the first direction). The wiring having a strip shape as a whole may be formed of a main wiring extending in a strip shape and a plurality of branch wirings each extending from the main wiring.

In the electronic device according to the first and second embodiments, the first wiring is formed of a plurality of wirings, and each of the wirings extends in the first direction as a whole. The second wiring is also formed of a plurality of wirings, and each of the wirings extends in the second direction different from the first direction (for example, in a direction perpendicular to the first direction) as a whole. Alternatively/additionally, the first wiring may be formed of a common wiring (common electrode), the second wiring may be formed of a plurality of wirings, and each of the wirings may extend in one direction as a whole. Alternatively/additionally, the first wiring may be formed of a plurality of wirings, each of the wirings extending in one direction as a whole, and the second wiring may be formed of a common wiring (common electrode). Alternatively, the first wiring may be formed of a common wiring (common electrode), and the second wiring may also be formed of a common wiring (common electrode). The wiring may be formed of, for example, a main wiring and a plurality of branch wirings each extending from the main wiring.

Examples of the materials of the first and second wirings include various metals, such as gold (Au), silver (Ag), copper (Cu), palladium (Pd), platinum (Pt), chromium (Cr), nickel (Ni), cobalt (Co), zirconium (Zr), aluminum (Al), tantalum (Ta), niobium (Nb), molybdenum (Mo), tungsten (W), titanium (Ti), iron (Fe), indium (In), zinc (Zn), tin (Sn), and the like; alloys (e.g., MoW) or compounds (e.g., TiW, nitrides such as TiN, WN, and the like, silicides such as WSi₂, MoSi₂, TiSi₂, TaSi₂, and the like) containing these metal elements; conductive particles made of any one of these metals; conductive particles made of an alloy containing these metal elements; semiconductors, such as silicon (Si) and the like; carbon thin films, such as diamond and the like; and conductive metal oxides, such as ITO (indium tin oxide), indium oxide, zinc oxide, and the like. Alternatively, each of the first and second wirings may have a laminated structure including layers containing these elements. Examples of the materials of the first and second wirings also include organic materials (conductive polymers) such as poly(3,4-ethylenedioxythiophene)/polystyrene sulfonic acid (PEDOT/PSS). The method of forming the first and second wirings depends on the material constituting these wirings. Examples of the formation method include various physical vapor deposition methods (PVD methods), such as vacuum deposition methods such as an electron beam evaporation method and a thermal filament evaporation method, a sputtering method, an ion plating method, and a laser abrasion method; various chemical vapor deposition methods (CVD methods) such as a MOCVD method; a spin coating method; various printing methods such as a screen printing method, an ink jet printing method, an offset printing method, a metal mask printing method, and a gravure printing method; various coating methods, such as an air doctor coating method, a blade coating method, a rod coating method, a knife coating method, a squeeze coating method, a reverse roll coating method, a transfer roll coating method, a gravure coating method, a kiss coating method, a cast coating method, a spray coating method, a slit orifice coating method, a calender coating method, and an immersion method; a stamping method; a lift-off method; a shadow mask method; plating methods, such as an electrolytic plating method, an electroless plating method, and a combination of thereof; a lift-off method; a sol-gel method; and and a spray method. Any one of these methods may be employed in combination with a patterning technique, if necessary. Examples of the PVD methods include (a) various vacuum deposition methods such as an electron beam heating method, a resistance heating method, and a flash evaporation method; (b) a plasma deposition method; (c) various sputtering methods such as a bipolar sputtering method, a DC sputtering method, a DC magnetron sputtering method, an RF sputtering method, a magnetron sputtering method, an ion beam sputtering method, and a bias sputtering method; and (d) various ion plating methods such as a direct current (DC) method, an RF method, a multi-cathode method, an activated reactive method, an electric field evaporation method, an RF ion plating method, and a reactive ion plating method. The material of the first wiring and the material of the second wiring may be the same or different. Moreover, by appropriately selecting the formation method, the first and second wirings which are directly patterned may be formed.

Examples of the materials of the extraction electrode includes the above-mentioned various materials of the first and second wirings. Moreover, examples of the formation method of the extraction electrode include the above-mentioned various PVD methods. Furthermore, by appropriately selecting the formation method, the extraction electrode which is directly patterned may be formed.

Examples of the material of the insulating layer include inorganic insulating materials such as silicon oxide materials, silicon nitrides (SiN_{Y}), and metal oxide high dielectric insulating films; and organic insulating materials such as polymethyl methacrylate (PMMA), polyvinylphenol (PVP), and polyvinyl alcohol (PVA). These materials may be used in combinations. Examples of the material of the insulating layer may also include photosensitive insulating materials (e.g., photosensitive polyimide resins and photosensitive polyamide resins). Examples of the silicon oxide materials include silicon oxides (SiO_{X}), silicon oxynitride (SiON), SOG (spin on glass), and low-dielectric constant SiO_{X} materials (e.g., polyaryl ethers, cycloperfluorocarbon polymers, benzocyclobutene, cyclic fluorocarbon resins, polytetrafluoroethylene, fluorinated aryl ethers, fluorinated polyimides, amorphous carbon, and organic SOG). Examples of a method of forming the insulating layer include the above-mentioned various PVD methods, the above-mentioned various CVD methods, a spin coating method, the above-mentioned various printing methods, the above-mentioned various coating methods, an immersion method, a casting method, and a spray method.

In the embodiment including preferred structures described above, the material of the adhesive constituting the adhesive layer and the second insulating layer is not particularly limited as long as it exhibits an adhesive function based on any method. Examples of such materials include materials that exhibit an adhesive function by being irradiated with energy rays, such as light (in particular, ultraviolet rays), radiation rays (such as X rays), or electron beams and materials that exhibit an adhesive function by being subjected to heat, pressure, or the like. Examples of the materials that can be easily formed and that can exhibit an adhesive function include resin-based adhesive materials, in particular, a photosensitive adhesive, a thermosetting adhesive, and a thermoplastic adhesive. Examples of the photosensitive adhesive include various known kinds of photosensitive adhesives. Specific examples thereof include negative-type photosensitive adhesives, such as polyvinyl cinnamate and polyvinyl azidobenzal, in which exposed portions become hardly soluble by a photocrosslinking reaction, and acrylamide in which exposed portions become hardly soluble by a photopolymerization reaction; and positive-type photosensitive adhesives, such as o-quinonediazide-novolak resins, in which a quinonediazide group produces a carboxylic acid by a photodegradation and the resins become easily soluble. Examples of the thermosetting adhesive include various known kinds of thermosetting adhesives. Specific examples thereof include epoxy resins, phenolic resins, urea resins, melamine resins, unsaturated polyester resins, polyurethane resins, and polyimide resins. Furthermore, examples of the thermoplastic adhesive include various known kinds of thermoplastic adhesives. Specific examples thereof include polyethylene resins, polystyrene resins, polyvinyl chloride resins, and polyamide resins. For example, when a photosensitive adhesive is used, an adhesive function can be imparted to the adhesive layer by irradiating the adhesive layer with light or ultraviolet rays. When a thermosetting adhesive is used, an adhesive function can be imparted to the adhesive layer by heating the adhesive layer with a hot plate, an oven, a heat press device, a heat roller, or the like. When a thermoplastic adhesive is used, an adhesive function can be imparted to the adhesive layer by selectively heating a part of the adhesive layer by, for example, irradiation of light to melt the part and impart flowability, and then cooling the adhesive layer. In addition, other examples of the adhesive layer include pressure-sensitive adhesive layers (made of an acrylic resin or the like) and layers that originally have an adhesive function and exhibit the adhesive function by only forming a layer without a further process.

Examples of the electronic device include a light-emitting diode display device, a backlight including light-emitting diodes, a light-emitting diode lighting system, and an advertising medium. The electronic device is not particularly limited and may be a portable electronic device or a non-portable electronic device. Specific examples thereof include a cellular phone, a mobile device, a robot, a personal computer, a device for automobile use, and various home electric appliances. For example, a diode formed of a nitride-based III-V group compound semiconductor can be used as a red light-emitting diode, a green light-emitting diode, and a blue light-emitting diode. For example, a diode formed of an AlGaInP-based compound semiconductor can be used as a red light-emitting diode.

In the present invention, examples of compound semiconductors which constitute the first compound semiconductor layer, the active layer, the second compound semiconductor layer include GaN-based compound semiconductors (including AlGaN mixed crystals, AlGaInN mixed crystals, and GaInN mixed crystals), GaInNAs-based compound semiconductors (including GaInAs mixed crystals and GaNAs mixed crystals), AlGaInP-based compound semiconductors, AlAs-based compound semiconductors, AlGaInAs-based compound semiconductors, AlGaAs-based compound semiconductors, GaInAs-based compound semiconductors, GaInAsP-based compound semiconductors, GaInP-based compound semiconductors, GaP-based compound semiconductors, InP-based compound semiconductors, InN-based compound semiconductors, and AIN-based compound semiconductors. Examples of the n-type impurities added to the compound semiconductor layers include silicon (Si), selenium (Se), germanium (Ge), tin (Sn), carbon (C), and titanium (Ti). Examples of the p-type impurities include zinc (Zn), magnesium (Mg), beryllium (Be), cadmium (Cd), calcium (Ca), barium (Ba), and oxygen (O). The active layer may include a single compound semiconductor layer or may have a single quantum well structure (QW structure) or a multiquantum well structure (MQW structure). Examples of a method of forming various compound semiconductor layers including the active layer include a metalorganic chemical vapor deposition method (MOCVD method and MOVPE method), a metalorganic molecular beam epitaxial method (MOMBE method), and a hydride vapor phase epitaxy method (HVPE method) in which halogen contributes to transport or reaction. In order to manufacture the light-emitting diodes which emit red light, the light-emitting diodes which emit green light, and the light-emitting diodes which emit blue light, the above-mentioned compound semiconductors and the compositions thereof may be appropriately selected.

When the first conductivity type is an n type, the second conductivity type is a p type, while when the first conductivity type is a p type, the second conductivity type is an n type.

In order to electrically connect the first electrode to the first compound semiconductor layer, for example, the first electrode may be formed on the first compound semiconductor layer. Similarly, in order to electrically connect the second electrode to the second compound semiconductor layer, for example, the second electrode may be formed on the second compound semiconductor layer. When the first conductivity type is an n type and the second conductivity type is a p type, the first electrode is an n-side electrode and the second electrode is a p-side electrode. In contrast, when the first conductivity type is a p type and the second conductivity type is an n type, the first electrode is a p-side electrode and the second electrode is an n side electrode. Examples of the p-side electrode include, Au/AuZn, Au/Pt/Ti(/Au)/AuZn, Au/Pt/TiW(/Ti)(/Au)/AuZn, Au/AuPd, Au/Pt/Ti(/Au)/AuPd, Au/Pt/TiW(/Ti)(/Au)/AuPd, Au/Pt/Ti, Au/Pt/TiW(/Ti), Au/Pt/TiW/Pd/TiW(/Ti), Ti/Cu, Pt, Ni, Ag, and Ge. Moreover, examples of the n-side electrode include Au/Ni/AuGe, Au/Pt/Ti(/Au)/Ni/AuGe, AuGe/Pd, Au/Pt/TiW(/Ti)/Ni/AuGe, and Ti. In this expression, layers further to the left relative to are more electrically separated from the active layer. Alternatively/additionally, the first electrode may be formed of a transparent conductive material such as ITO, IZO, ZnO:Al, or ZnO:B. In the case where a layer made of a transparent conductive material is used as a current-diffusion layer and the first electrode is used as an n-side electrode, a metal laminated structure described in the case where the first electrode is used as a p-side electrode may be used in combination.

Examples of the light-emitting diode production substrate include a GaAs substrate, a GaP substrate, an AIN substrate, an AIP substrate, an InN substrate, an InP substrate, an AlGaInN substrate, an AlGaN substrate, an AlInN substrate, a GaInN substrate, an AlGaInP substrate, an AlGaP substrate, an AlInP substrate, a GaInP substrate, a ZnS substrate, a sapphire substrate, a SiC substrate, an alumina substrate, a ZnO substrate, a LiMgO substrate, a LiGaO₂ substrate, a MgAl₂O₄ substrate, a Si substrate, a Ge substrate, and a substrate in which an underlayer or a buffer layer is provided on a surface (principal surface) of any of these substrates. In order to manufacture the light-emitting diodes which emit red light, the light-emitting diodes which emit green light, and the light-emitting diodes which emit blue light, substrates may be appropriately selected from these substrates.

Examples of the materials which constitute the support substrate and the various substrates used in the various manufacturing process steps include sapphire substrate, a glass plate, a metal plate, an alloy plate, a ceramic plate, and a plastic plate, in addition to the above-mentioned materials constituting the light-emitting device production substrate. Examples of a method of fixing or bonding the various kinds of substrates include a method using an adhesive material, a metal bonding method, a semiconductor bonding method, and a metal-semiconductor bonding method. On the other hand, examples of the method of separating or removing the various kinds of substrates include a laser-abrasion method, a heating method, and an etching method.

Examples of a method of separating the semiconductor light-emitting devices or the light-emitting device portions from the support substrate or the like include a laser irradiation method, a dry etching method, a wet etching method, or a dicing method.

### Example 1

Example 1 relates to the semiconductor light-emitting device according to the first and second embodiments and the semiconductor light-emitting device assembly manufacturing method according to the embodiment.

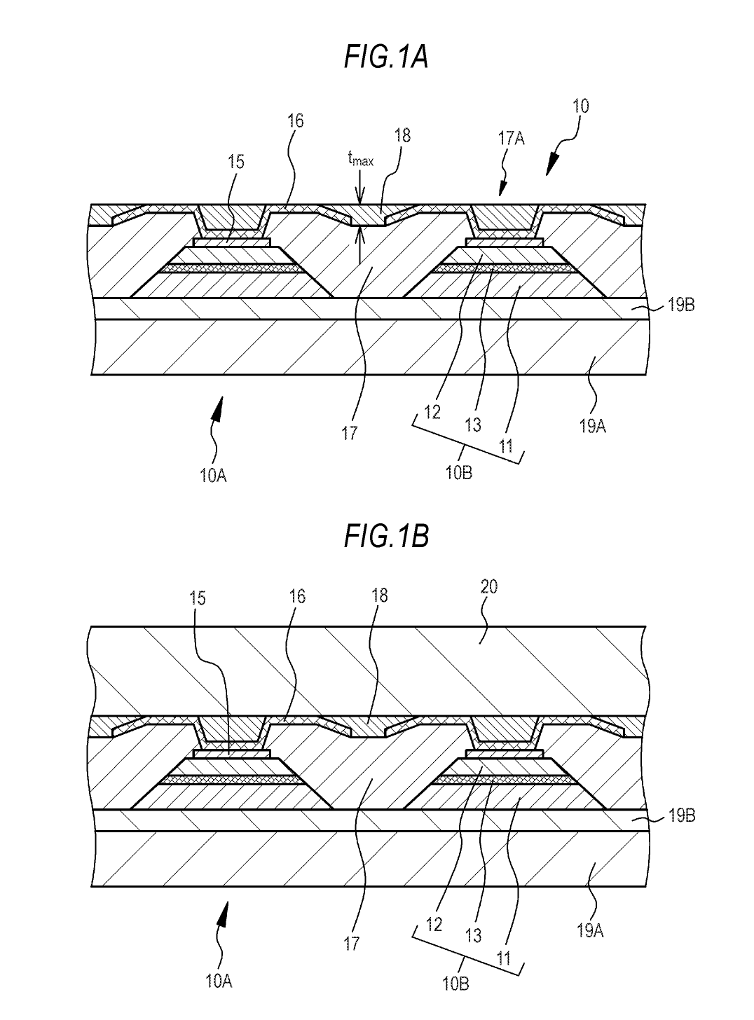

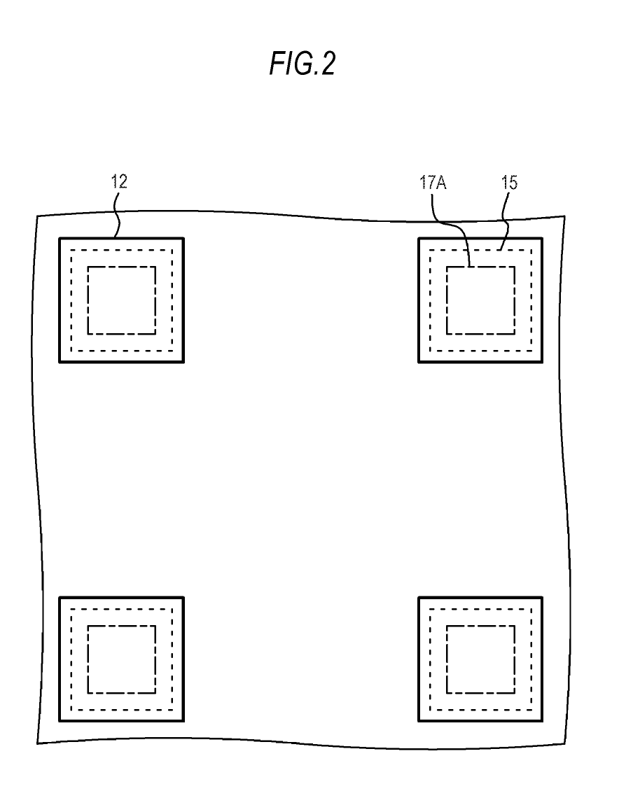

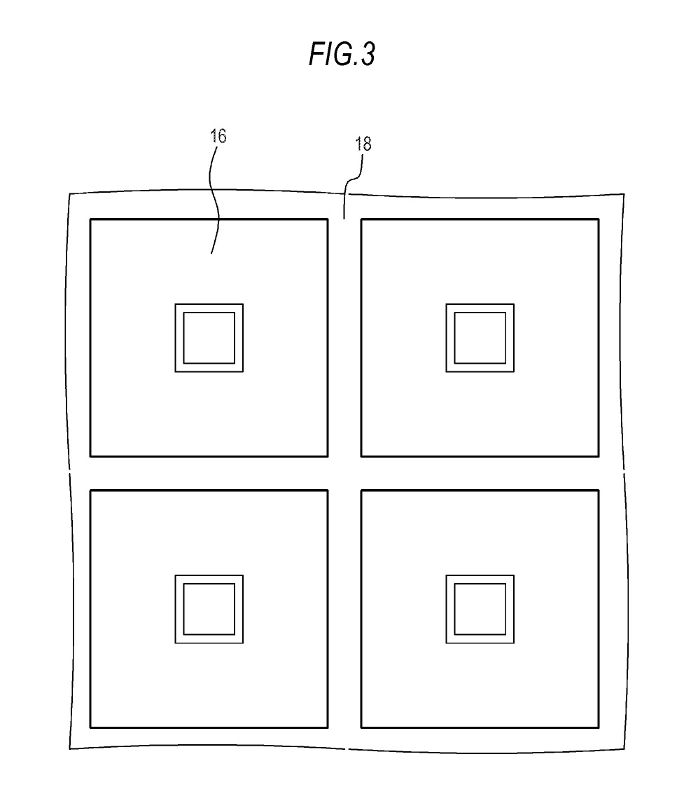

FIGS. 1A and 1B show schematic partial cross-sectional views of a semiconductor light-emitting device according to Example 1 (specifically, a light-emitting diode LED in Example 1). FIG. 2 is a schematic diagram showing the arrangement of the outer edge of a top peripheral portion of a second compound semiconductor layer, a second electrode, and an opening portion provided to an insulating layer of the semiconductor light-emitting device according to Example 1. FIG. 3 is a schematic diagram showing the shape of the outer edge of an extraction electrode 16 of the semiconductor light-emitting device according to Example 1.

A semiconductor light-emitting device (light-emitting diode 10) according to Example 1 includes:

(a) a light-emitting device portion 10A including a laminated structure 10B, in which a first compound semiconductor layer 11 having a first conductivity type (specifically, in Example 1, an n type), an active layer 13, and a second compound semiconductor layer 12 having a second conductivity type (specifically, in Example 1, a p type) different from the first conductivity type are sequentially laminated, and a second electrode 15 provided on the second compound semiconductor layer 12;

(b) an insulating layer 17 that covers a side surface of the light-emitting device portion 10A and a top peripheral portion of the second compound semiconductor layer 12 and has an opening portion 17A in which a top central portion of the second electrode 15 is exposed;

(c) an extraction electrode 16 that is formed on the insulating layer 17 so as to extend from the exposed top surface of the second electrode 15 to the insulating layer 17; and

(d) a first electrode 14 that is electrically connected to the first compound semiconductor layer 11.

FIG. 1A shows a state before the support substrate 20 is bonded thereto, and FIG. 1B shows a state where the support substrate 20 is bonded thereto. The first electrode 14 is not shown in FIGS. 1A and 1B.

In the semiconductor light-emitting device (the light-emitting diode 10) according to Example 1, when expressed based on the semiconductor light-emitting device according to the first embodiment, the second insulating layer (or the adhesive layer) 18 formed of an adhesive is directly formed on a portion of the extraction electrode 16, and the second insulating layer (or the adhesive layer 18) is not formed on the remaining portions of the extraction electrode 16. Moreover, when expressed based on the semiconductor light-emitting device according to the second embodiment, the planar shape of the opening portion 17A of the insulating layer 17 is rectangular as shown in the partial plan view of the opening portion 17A of the insulating layer 17 in FIG. 2. Here, the planar shape of the second compound semiconductor layer 12 is also rectangular (each side is 14 μm±1 μm). Furthermore, the planar shape of the opening portion 17A of the insulating layer 17 is similar to the planar shape of the second compound semiconductor layer 12. In FIG. 2, the outer edge of the top peripheral portion of the second compound semiconductor layer 12 is shown by a solid line, the outer edge of the second electrode 15 is shown by a dotted line, and the opening portion 17A of the insulating layer 17 is shown by the one-dot chain lines.

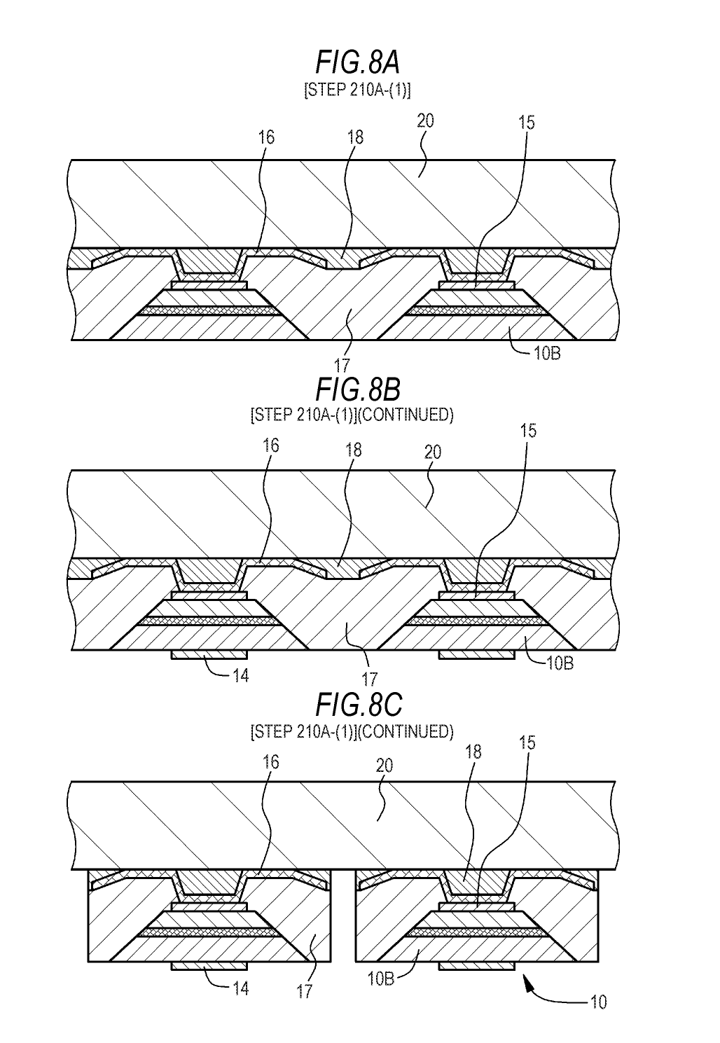

In Example 1, when the semiconductor light-emitting device emits red light, the first compound semiconductor layer 11, the active layer 13, and the second compound semiconductor layer 12 may be formed of AlGaInP-based compound semiconductors. When the semiconductor light-emitting device emits green light, the first compound semiconductor layer 11, the active layer 13, and the second compound semiconductor layer 12 may be formed of InGaN-based compound semiconductors. When the semiconductor light-emitting device emits blue light, the first compound semiconductor layer 11, the active layer 13, and the second compound semiconductor layer 12 may be formed of InGaN-based compound semiconductors. Moreover, although the first compound semiconductor layer 11 is electrically connected to the first electrode 14, specifically, the first electrode 14 is formed on the first compound semiconductor layer 11 as shown in FIG. 8B described later. In Example 1, since the first conductivity type is the n type and the second conductivity type is the p type, the first electrode 14 is an n-side electrode and the second electrode 15 is a p-side electrode. Specifically, the second electrode 15 is formed of an ohmic contact material such as Ni, and the first electrode 14 is formed of an ohmic contact material such as Ti. In addition, the insulating layer 17 is formed of a photosensitive polyimide resin, and the second insulating layer (adhesive layer) 18 is formed of an epoxy-based thermosetting resin.

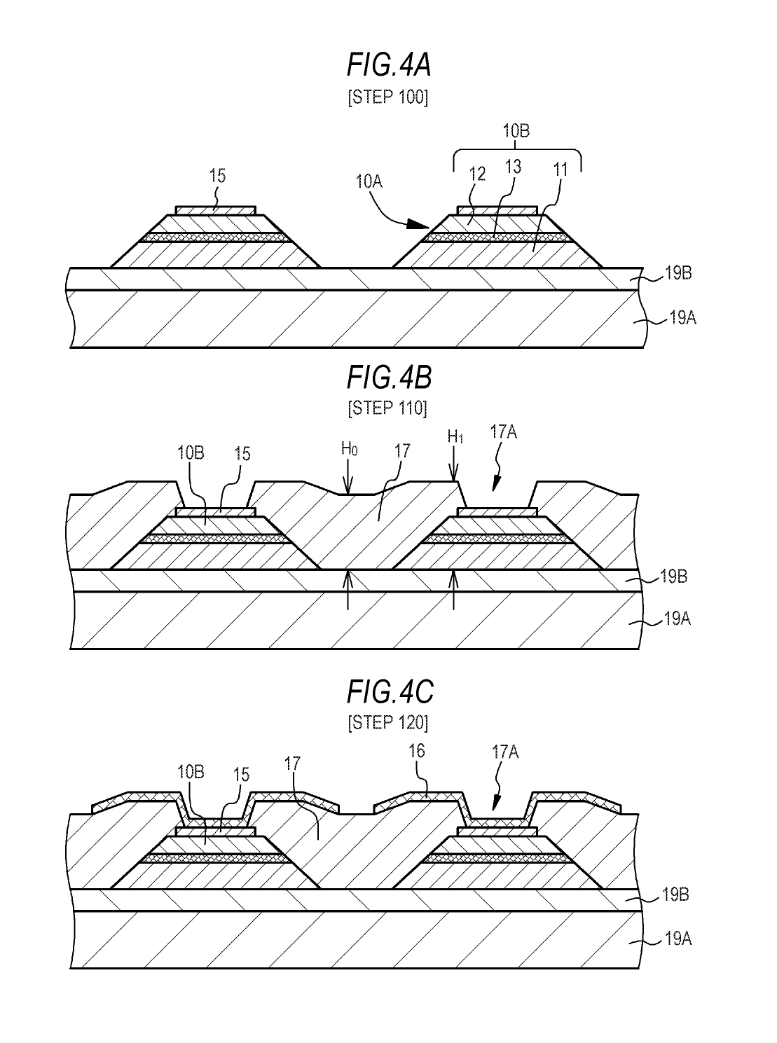

Hereinafter, a semiconductor light-emitting device assembly manufacturing method according to Example 1 will be described with reference to the schematic partial cross-sectional views of the light-emitting device production substrate and the like shown in FIGS. 1A and 1B and FIGS. 4A to 4C.

Step 100

First, by a well-known method, a plurality of light-emitting device portions 10A are formed on a light-emitting device production substrate 19A so as to be separated from each other. The plurality of light-emitting device portions 10A each includes a laminated structure 10B, in which a first compound semiconductor layer 11 having a first conductivity type, an active layer 13, and a second compound semiconductor layer 12 having a second conductivity type different from the first conductivity type are sequentially laminated, and a second electrode 15 provided on the second compound semiconductor layer 12 (see FIG. 4A).

Specifically, a buffer layer 19B is formed on a light-emitting diode production substrate 19A including, for example, a sapphire substrate having a nominal diameter of 2 inches by a MOCVD method. Subsequently, the first compound semiconductor layer 11 having an n-conductivity type, the active layer 13, and the second compound semiconductor layer 12 having a p-conductivity type are formed in that order on the buffer layer 19B by a MOCVD method. After the second electrode 15 which is a p-side electrode is formed on the second compound semiconductor layer 12 by a lift-off method and a vacuum evaporation method, the first compound semiconductor layer 11, the active layer 13, and the second compound semiconductor layer 12 are patterned, whereby a plurality of light-emitting device portions 10A which are separated from each other is obtained. Alternatively/additionally, after the first compound semiconductor layer 11, the active layer 13, and the second compound semiconductor layer 12 are patterned to obtain a plurality of light-emitting device portions 10A which are separated from each other, the second electrode 15 which is the p-side electrode may be formed on the second compound semiconductor layer 12 by a lift-off method and a vacuum evaporation method.

Step 110

Subsequently, an insulating layer 17 is formed having an opening portion 17A in which a top central portion of the second electrode 15 of the light-emitting device portion 10A is exposed. Specifically, a photosensitive polyimide resin is coated on the entire surface by a spin coating method. After that, the photosensitive polyimide resin is exposed using a mask (not shown), and the photosensitive polyimide resin is subjected to development and curing, whereby the insulating layer 17 is obtained having the opening portion 17A in which the top central portion of the second electrode 15 of the light-emitting device portion 10A is exposed (see FIG. 4B). The planar shape of the opening portion 17A of the insulating layer 17 is rectangular, and the planar shape of the opening portion 17A of the insulating layer 17 is similar to the planar shape of the compound semiconductor layer 12 (see FIG. 2).

Step 120

Subsequently, an extraction electrode 16 which is patterned is provided to each light-emitting device portion 10A so as to extend from a top surface of the second electrode 12 exposed to a bottom portion of the opening portion 17A to the insulating layer 17 (see FIG. 4C). Specifically, the extraction electrode 16 can be obtained by forming an extraction electrode layer formed of a laminated structure of a titanium layer (lower layer)/copper layer (upper layer) on the insulating layer 17 so as to extend from the top surface of the second electrode 12 exposed to the bottom portion of the opening portion 17A by a physical vapor deposition method (PVD method) such as a sputtering method and then patterning the extraction electrode layer by a well-known method. Here, an average thickness of the extraction electrode 16 on the top surface of the second electrode 12 is set to 0.55 Moreover, as shown in FIG. 4B, when it is assumed that as measured from a surface of the first compound semiconductor layer 11 opposing a surface thereof being in contact with the active layer 13, the height of the thinnest portion of the insulating layer 17 formed on a region of the light-emitting device production substrate 19A disposed between the adjacent light-emitting device portions 10A is H₀, and the height of the thickest portion of the insulating layer 17 covering the outer peripheral portion of the second electrode 15 is H₁, a relation H₁−H₀≦1.5 (m) is satisfied.

Step 130

Subsequently, an adhesive layer 18 is formed so as to cover the entire surface, and the support substrate 20 is attached using the adhesive layer 18. Here, the adhesive layer 18 in which a portion of the extraction electrode 16 is exposed is directly formed on the extraction electrode 16 (see FIG. 1A). Specifically, the adhesive layer 18 formed of an epoxy-based thermosetting resin is formed on the entire surface by a spin coating method, and the adhesive layer 18 is dried. Specifically, a droplet of an adhesive is dropped on a portion of the adhesive layer 18 in which a portion of the extraction electrode 16 is exposed (i.e., on the center of the light-emitting device production substrate 19A), and the light-emitting device production substrate 19A is pressed by a heat press machine so that the adhesive is uniformly extended. By appropriately adjusting properties such as a viscosity of the adhesive layer 18 and optimizing the spin coating condition, it is possible to form the adhesive layer 18, in which a portion of the extraction electrode 16 is exposed, directly on the extraction electrode 16. Here, the maximum thickness tmax (see FIG. 1A) of the adhesive layer (second insulating layer) 18 in the outer peripheral portion of each light-emitting device portion 10A (or each light-emitting diode 10) is 1 μm or less. After that, the support substrate 20 formed of a sapphire substrate is attached by the adhesive layer 18 using a heat press machine (see FIG. 1B).

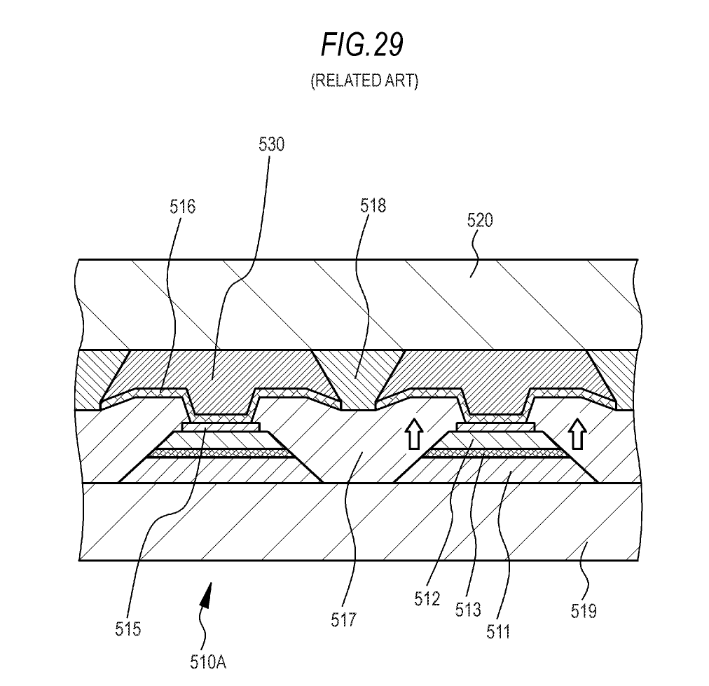

A light-emitting diode was produced using the light-emitting device portion 10A obtained in Example 1. Moreover, a light-emitting diode (Comparative Example 1) having a related-art structure shown in FIG. 29 was produced. The operating voltage and the optical power of the light-emitting diodes according to Example 1 and Comparative Example 1 were measured. The operating voltage was increased by maximum of 1.5 volts and the optical power was decreased by maximum of about 50% for Comparative Example 1 compared to those of Example 1. The thicknesses of each part of the light-emitting diodes of Example 1 and Comparative Example 1 were as shown in Table 1 below. In Table 1, “Thickness on Resin Layer” refers to the thickness of a layer (not shown) provided between the support substrate 20 and the adhesive layer 18 or the extraction electrode 16.

TABLE 1

| | | Comparative |
|---|---|---|
| | Example 1 | Example 1 |
| Thickness on Resin layer | 2.1 μm | 0.8 μm |
| Copper-plating Layer Thickness | | 1.3 μm |
| Extraction Electrode Thickness | 0.55 μm | 0.55 μm |
| Second Electrode Thickness | 0.35 μm | 0.35 μm |
| Laminated Structure Thickness | 2.8 μm | 2.8 μm |

In the semiconductor light-emitting device according to Example 1, the second insulating layer (or the adhesive layer) 18 formed of an adhesive is directly formed on a portion of the extraction electrode 16, and the second insulating layer (or the adhesive layer) 18 is not formed on the remaining portions of the extraction electrode 16. Therefore, it is possible to reduce the amount of contraction during curing of the second insulating layer (or the adhesive layer) 18. As a result, it is possible to achieve a reduction in stress occurring in the semiconductor light-emitting device or the light-emitting device portion 10A when the light-emitting device production substrate 19A having the light-emitting device portions 10A constituting the semiconductor light-emitting device formed thereon is bonded to another substrate (the support substrate 20). Moreover, the planar shape of the second compound semiconductor layer 12 and the p-side electrode of the opening portion 17A of the insulating layer 17 are rectangular. Therefore, it is possible to achieve a reduction in the area of the second insulating layer (or the adhesive layer) 18 occupying the upper portion of the extraction electrode 16. As a result, it is possible to achieve a reduction in stress occurring in the semiconductor light-emitting device or the light-emitting device portion. Moreover, from the above-mentioned results, as described above, it is possible to certainly prevent occurrence of such a problem that characteristic deterioration such as an increased driving voltage or a decreased optical power occurs in the semiconductor light-emitting devices. Furthermore, since the second insulating layer (or the adhesive layer) 18 formed of an adhesive is directly formed on a portion of the extraction electrode 16, and the second insulating layer (or the adhesive layer) 18 is not formed on the remaining portions of the extraction electrode 16, it is possible to maintain a high degree of flatness of the semiconductor light-emitting device or the light-emitting device portion, which leads to improved process reliability and improved reliability of the semiconductor light-emitting device or the light-emitting device portion.

In this way, it is possible to obtain the semiconductor light-emitting device according to Example 1. In order to obtain the electronic device according to the first and second embodiments and the image display device according to the first and second embodiments, it is necessary to execute steps described in Example 2 in succession to the above-mentioned steps.

### Example 2

Example 2 relates to the electronic device according to the first and second embodiments and the image display device according to the first and second embodiments.

An electronic device or an image display device according to Example 2 includes:

(A) a plurality of first wirings extending in a first direction;

(B) a plurality of second wirings extending in a second direction different from the first direction; and

(C) a first connection portion and a second connection portion, wherein:

the first connection portion is electrically connected to the first wirings, the second connection portion is electrically connected to the second wirings, and the electronic device or the image display device includes a plurality of semiconductor light-emitting devices.

Specifically, each semiconductor light-emitting device (each light-emitting diode 10) is configured by the semiconductor light-emitting device (the light-emitting diode) described in Example 1. That is to say, specifically, each semiconductor light-emitting device (each light-emitting diode 10) includes:

(a) a light-emitting device portion 10A including a laminated structure 10B, in which a first compound semiconductor layer 11 having a first conductivity type, an active layer 13, and a second compound semiconductor layer 12 having a second conductivity type different from the first conductivity type are sequentially laminated, and a second electrode 15 provided on the second compound semiconductor layer 12;

(b) an insulating layer 17 that covers a side surface of the light-emitting device portion 10A and a top peripheral portion of the second compound semiconductor layer 12 and has an opening portion 17A in which a top central portion of the second electrode 15 is exposed;

(c) an extraction electrode 16 that is formed on the insulating layer 17 so as to extend from the exposed top surface of the second electrode 15 to the insulating layer 17; and

(d) a first electrode 14 that is electrically connected to the first compound semiconductor layer 11, wherein:

the extraction electrode 16 is electrically connected to a second connection portion or forms a second connection portion; and

the first electrode 14 is electrically connected to a first connection portion or forms a first connection portion.

Moreover, a second insulating layer 18 formed of an adhesive is directly formed on a portion of the extraction electrode 16 but is not formed on the remaining portions of the extraction electrode 16. Alternatively/additionally, the planar shape of the opening portion 17A of the insulating layer 17 is rectangular.

More specifically, the image display device according to Example 2 is configured by a light-emitting diode display device. Here, one pixel of the light-emitting diode display device includes a group (light-emitting unit) includes a first light-emitting diode 110, a second light-emitting diode 210, and a third light-emitting diode 310. Here, the first light-emitting diode 110, the second light-emitting diode 210, and the third light-emitting diode 310 are each configured by the semiconductor light-emitting device described in Example 1. Moreover, a plurality of light-emitting units are arranged in a first direction and a second direction perpendicular to the first direction, i.e., arranged in a two-dimensional matrix. In addition, in each light-emitting unit, a first electrode 114 of the first light-emitting diode 110, a first electrode 214 of the second light-emitting diode 210, and a first electrode 314 of the third light-emitting diode 310 are connected to the first connection portion (hereinafter sometimes referred to as “sub-common electrode 43). On the other hand, in each light-emitting unit arranged in the second direction, a second electrode (more specifically, an extraction electrode 116) of the first light-emitting diode 110 is connected to a second wiring (hereinafter referred to as “a first common electrode” or “a first common wiring” 401) extending in the second direction. Moreover, a second electrode (more specifically, an extraction electrode 216) of the second light-emitting diode 210 is connected to a second wiring (hereinafter referred to as “a second common electrode” or “a second common wiring” 402) extending in the second direction. Furthermore, a second electrode (more specifically, an extraction electrode 316) of the third light-emitting diode 310 is connected to a second wiring (hereinafter referred to as “a third common electrode” or “a third common wiring” 403) extending in the second direction. In addition, the sub-common electrode 43 in each light-emitting unit arranged in the second direction is connected to a first wiring (hereinafter referred to as “a fourth common electrode” or “a fourth common wiring” 404) extending in the first direction.

When it is assumed that a desired number of the first light-emitting diodes constituting one light-emitting unit is N₁, a desired number of the second light-emitting diodes constituting one light-emitting unit is N₂, and a desired number of the third light-emitting diodes constituting one light-emitting unit is N₃, the number N₁ may be an integer of 1 or 2 or more, the number N₂ may be an integer of 1 or 2 or more, and the number N₃ may be an integer of 1 or 2 or more. The numbers N₁, N₂, and N₃ may be the same or different. When the numbers N₁, N₂, and N₃ are each an integer of 2 or more, the light-emitting diodes may be connected in series or in parallel in one light-emitting unit. Examples of the combination of the numbers (N₁, N₂, N₃) include, but are not limited to, (1, 1, 1), (1, 2, 1), (2, 2, 2), and (2, 4, 2). In Example 2, the specific combination of the numbers (N₁, N₂, N₃) is (1, 1, 1). The light-emitting diode display device or the electronic device according to Example 2 includes a plurality of light-emitting units arranged in a first direction and a second direction perpendicular to the first direction, i.e., arranged in a two-dimensional matrix, each of the light-emitting units including a desired number of first light-emitting diodes 110 which emit red light, a desired number of second light-emitting diodes 210 which emit green light, and a desired number of third light-emitting diodes 310 which emit blue light.

In Example 2, the first compound semiconductor layer 11, the active layer 13, and the second compound semiconductor layer 12 in each of the first light-emitting diodes 110 which emit red light are formed of AlGaInP-based compound semiconductors. The first compound semiconductor layer 11, the active layer 13, and the second compound semiconductor layer 12 in each of the second light-emitting diodes 210 which emit green light are formed of InGaN-based compound semiconductors. The first compound semiconductor layer 11, the active layer 13, and the second compound semiconductor layer 12 in each of the third light-emitting diodes 310 which emit blue light are formed of InGaN-based compound semiconductors.

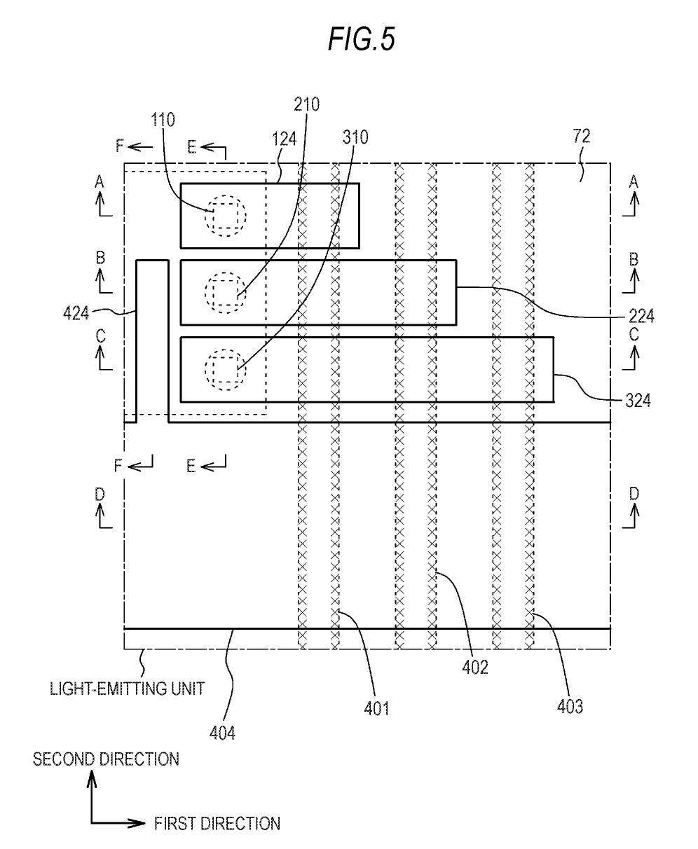

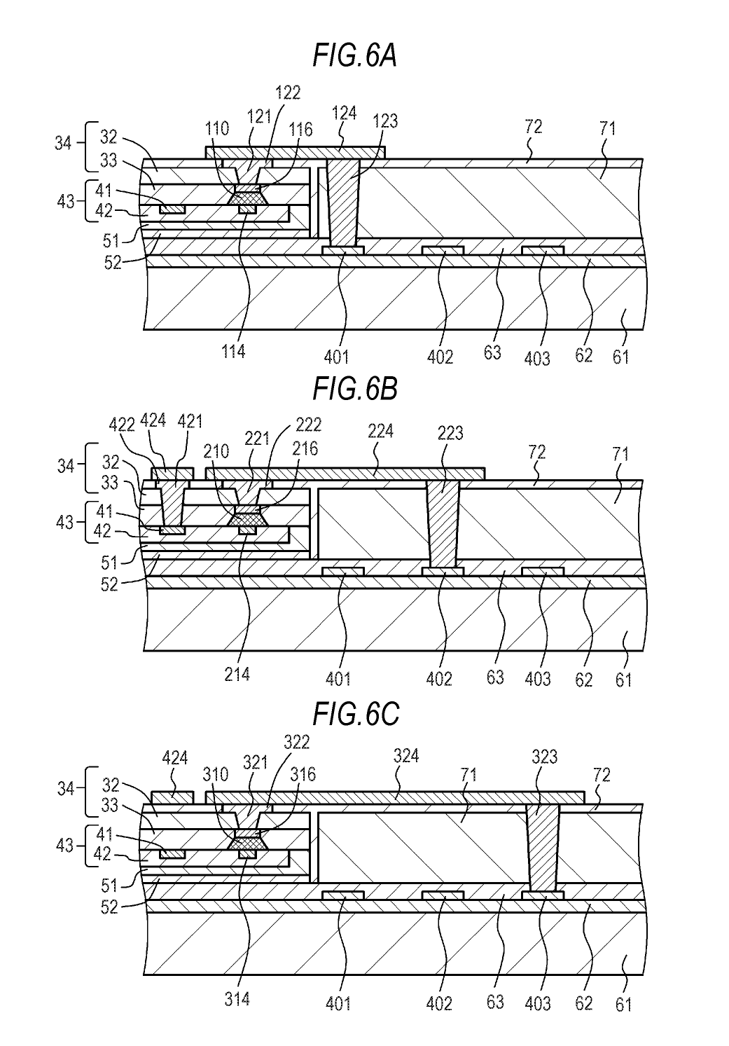

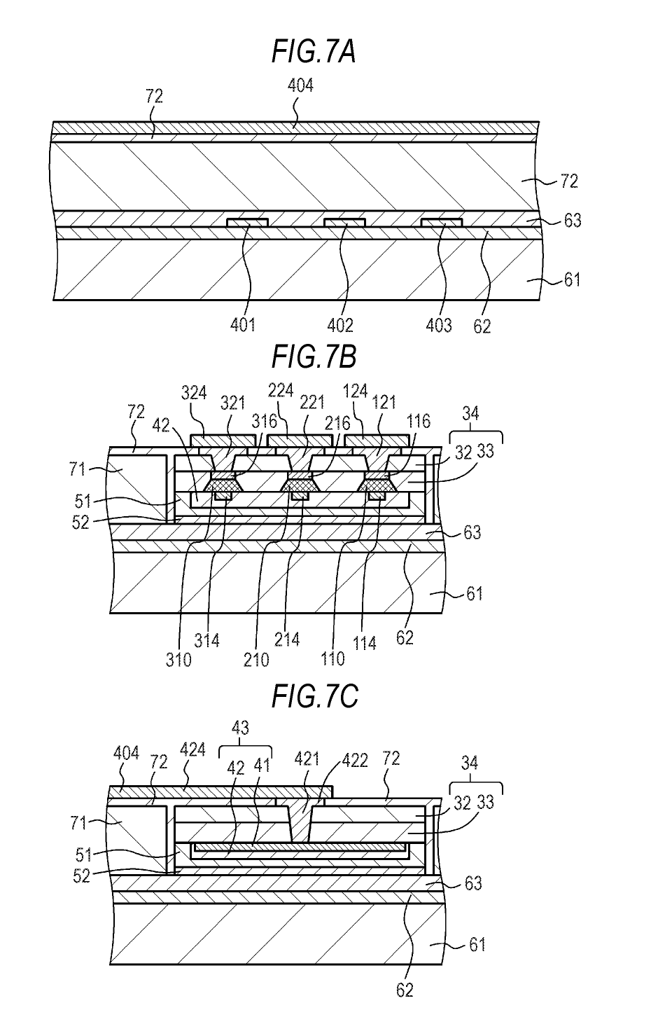

FIG. 5 is a schematic plan view of one light-emitting unit. FIGS. 6A, 6B, 6C, 7A, 7B, and 7C are schematic partial cross-sectional views taken along the arrows A-A, B-B, C-C, D-D, E-E, and F-F in FIG. 5. In FIG. 5, one light-emitting unit is shown by the one-dot chain lines, and the light-emitting diodes are shown by the dotted lines. In addition, the outer edges of the three second wirings (the first common electrode 401, the second common electrode 402, and the third common electrode 403) are cross-hatched, and the outer edges of the second connection portion (second A, B and C-connection portions 124, 224, and 324), the third connection portion 424, and the first wiring (the fourth common electrode 404) are shown by the solid lines.

The first common electrode 401, the second common electrode 402, and the third common electrode 403 are formed on a display substrate 61, and the sub-common electrode 43 is formed in a fixed layer 34 that is fixed on the display substrate 61. Furthermore, the first light-emitting diode 110, the second light-emitting diode 210, and the third light-emitting diode 310 in each of the light-emitting units are fixed in the fixed layer 34, and the fixed layer 34 is surrounded by a second insulating material layer 71. Here, the second insulating material layer 71 covers the first common electrode 401, the second common electrode 402, and the third common electrode 403 which are formed on the display substrate 61.

In the light-emitting diode display device or the electronic device according to Example 2, light emitted from the first light-emitting diode 110, the second light-emitting diode 210, and the third light-emitting diode 310 is emitted from the first electrode side. The sub-common electrode 43 has a light-transmitting structure. The sub-common electrode 43 may include a metal layer or an alloy layer. Alternatively/additionally, the sub-common electrode 43 may include a light-transmitting electrode 42 and a metal layer 41 that extends from the light-transmitting electrode 42. Moreover, the first light-emitting diode 110, the second light-emitting diode 210, and the third light-emitting diode 310 in each light-emitting unit are arranged on the sub-common electrode 43 in a state where the first electrodes 114, 214, and 314 are connected to the sub-common electrode 43. Specifically, the first electrodes 114, 214, and 314 of the first light-emitting diode 110, the second light-emitting diode 210, and the third light-emitting diode 310 are in contact with the light-transmitting electrode 42. More specifically, the light-transmitting electrode 42 is formed on the first electrodes 114, 214, and 314 and in the peripheries of the first electrodes 114, 214, and 314. On the other hand, a fourth contact hole portion 421 is in contact with the metal layer 41. Specifically, the fourth contact hole portion 421 is formed on the metal layer 41. The light-transmitting electrode 42 is formed of a transparent conductive material such as ITO or IZO. On the other hand, the metal layer 41 is formed of a general metal wiring material such as, for example, Au, Cu, and Al.

The sub-common electrode 43 may include a metal layer or an alloy layer, for example, and specifically, the sub-common electrode 43 may be a mesh-like electrode or a comb-like electrode. Alternatively/additionally, the sub-common electrode 43 may include a light-transmitting electrode and a metal layer or an alloy layer extending from the light-transmitting electrode. Specifically, the light-transmitting electrode may be formed of a transparent conductive material such as ITO or IZO, or the light-transmitting electrode may be a mesh-like electrode or a comb-like electrode. The mesh-like electrode or the comb-like electrode itself may not have light transmissivity as long as it has a light-transmitting structure. Examples of materials used for forming the metal layer or the alloy layer include metal elements such as Ti, Cr, Ni, Au, Ag, Cu, Pt, W, Ta, Al, and the like, and alloys thereof. The sub-common electrode 43 may have a multilayer structure including two or more layers. Although the first electrode of each of the first light-emitting diode, the second light-emitting diode, and the third light-emitting diode is in contact with the light-transmitting electrode, specifically the light-transmitting electrode may be formed on the first electrode or may be formed on the first electrode and in the peripheries of the first electrode. Although the fourth contact hole portion is preferably in contact with the metal layer or the alloy layer, specifically, the fourth contact hole portion may be formed on the metal layer or the alloy layer.

The second electrode (specifically, the extraction electrode 116) of the first light-emitting diode 110 is connected to the first common electrode 401 through a first contact hole portion 121 formed in the fixed layer 34 and the second connection portion (the second A-connection portion 124) that is formed on the second insulating material layer 71 so as to extend from an upper portion of the fixed layer 34 to the second insulating material layer 71. The second electrode (specifically, the extraction electrode 216) of the second light-emitting diode 210 is connected to the second common electrode 402 through a second contact hole portion 221 formed in the fixed layer 34 and the second connection portion (the second B-connection portion 224) that is formed on the second insulating material layer 71 so as to extend from the upper portion of the fixed layer 34. The second electrode (specifically, the extraction electrode 316) of the third light-emitting diode 310 is connected to the third common electrode 403 through a third contact hole portion 321 formed in the fixed layer 34 and the second connection portion (the second C-connection portion 324) that is formed on the second insulating material layer 71 so as to extend from the upper portion of the fixed layer 34. The first connection portion (the sub-common electrode 43) is connected to the first wiring (the fourth common electrode 404) formed on the second insulating material layer 71 through a fourth contact hole portion 421 formed in the fixed layer 34 and the third connection portion 424 that is formed on the second insulating material layer 71 so as to extend from the upper portion of the fixed layer 34 to the second insulating material layer 71. In addition, in Example 2, a first pad portion 122 formed on the fixed layer 34 is provided between the first contact hole portion 121 and the second A-connection portion 124. Moreover, a second pad portion 222 formed on the fixed layer 34 is provided between the second contact hole portion 221 and the second B-connection portion 224. Furthermore, a third pad portion 322 formed on the fixed layer 34 is provided between the third contact hole portion 321 and the second C-connection portion 324. Furthermore, a fourth pad portion 422 formed on the fixed layer 34 is provided between the fourth contact hole portion 421 and the third connection portion 424.

Further, the first, second, third, and fourth contact hole portions 121, 221, 321, and 421 are formed of a wiring material such as Al, or Cu. The first, second, third, and fourth pad portions 122, 222, 322, and 422 are formed of a wiring material such as Al or Cu. The second A, B, and C-connection portions 124, 224, and 324, and the third connection portion 424 are formed of a wiring material such as Al or Cu.

Although the first compound semiconductor layer 11 is electrically connected to the first electrodes 114, 214, and 314, specifically, the first electrodes 114, 214, and 314 are formed on the first compound semiconductor layer 11. Similarly, although the second compound semiconductor layer 12 is electrically connected to the second electrodes, specifically, the second electrodes are formed on the second compound semiconductor layer 12. In addition, the first, second, third, and fourth common electrodes 401, 402, 403, and 404 are formed of a wiring material such as Al or Cu. The fixed layer 34 has a two-layer structure including, for example, an insulating material layer 32 and a burying material layer 33 which are provided in that order from a first transfer substrate side. The insulating material layer 32 is formed of a polyimide resin, and the burying material layer 33 is formed of an ultraviolet-curable resin. The second insulating material layer 71 is formed of a polyimide resin. As an example of a method of fixing the first, second, and third light-emitting diodes 110, 210, and 310 to the fixed layer 34, a method can be used in which the burying material layer 33 is partially cured in advance while leaving the remaining portions uncured, the first, second, and the third light-emitting diodes 110, 210, and 310 are buried in the uncured portions of the burying material layer 33, and then the uncured portions of the burying material layer 33 is cured.

The material of the burying material layer 33 is not particularly limited as long as the material can be cured or solidified by any method. Examples of such materials include materials that can be cured or solidified by being irradiated with energy rays, such as light (in particular, ultraviolet rays), radiation rays (such as X rays), or electron beams and materials that can be cured or solidified by being subjected to heat, pressure, or the like. Specifically, examples of such materials include the above-mentioned various materials of the adhesive constituting the adhesive layer (the second insulating layer).

The first, second, third, and fourth contact hole portions may be formed using, for example, any one of the above-mentioned electrode materials. These contact hole portions may be formed by the same method as the formation method of opening regions in the fixed layer by a lithography technique or the formation method of the electrodes using the above-mentioned electrode material. The method of forming the first pad portion extending from the first contact hole portion to the fixed layer, the method of forming the second pad portion extending from the second contact hole portion to the fixed layer, the method of forming the third pad portion extending from the third contact hole portion to the fixed layer, and the method of forming the fourth pad portion extending from the fourth contact hole portion to the fixed layer may be appropriately selected from the above-mentioned methods of forming the common electrodes and the like. Furthermore, the method of forming the second connection portions (the second A, B, and C-connection portions) extending from the fixed layer to the second insulating material layer and the method of forming the third connection portion extending from the fixed layer to the second insulating material layer may be appropriately selected from the above-mentioned methods of forming the common electrodes and the like.

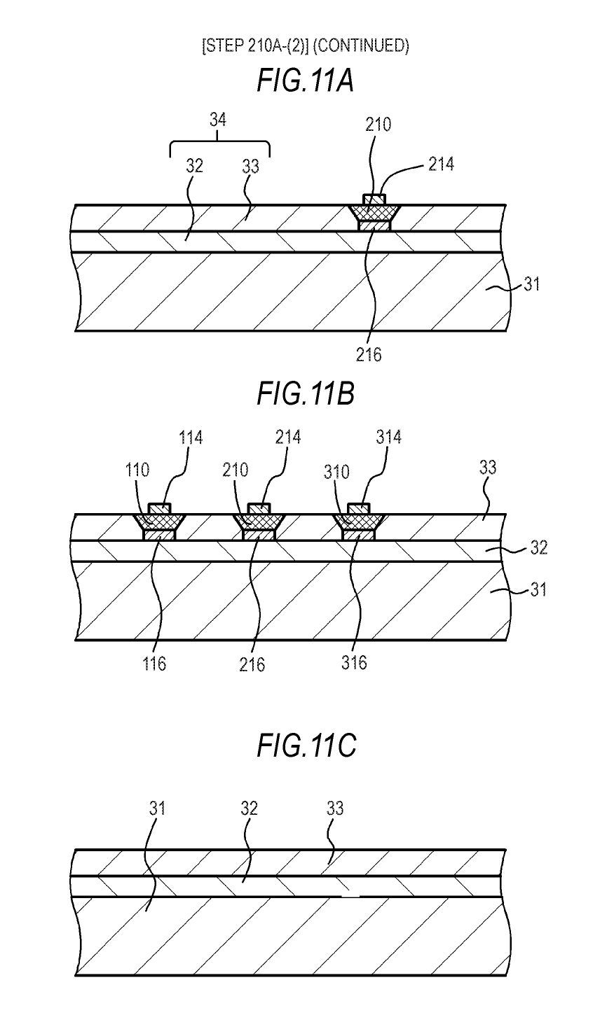

Next, a method of manufacturing the light-emitting diode display device or the electronic device according to Example 2 will be described with reference to FIGS. 8A, 8B, 8C, 9A, 9B, 10A, 10B, 11A, 11B, 11C, 12A, 12B, 12C, 13A, 13B, 13C, 14A, 14B, 14C, 15A, 15B, 15C, 16A, 16B, 16C, 17A, 17B, 17C, 18A, 18B, 18C, 19A, 19B, 19C, 20A, 20B, and 20C. In the drawings, FIGS. 11A, 12A, 13A, 14A, 15A, 16A, 17A, 18A, 19A, and 20A are schematic partial cross-sectional views equivalent to those taken along the arrows B-B in FIG. 5. FIGS. 11B, 12B, 13B, 14B, 15B, 16B, 17B, 18B, 19B, and 20B are schematic partial cross-sectional views equivalent to those taken along the arrows E-E in FIG. 5. FIGS. 11C, 12C, 13C, 14C, 15C, 16C, 17C, 18C, 19C, and 20C are schematic partial cross-sectional views equivalent to those taken along the arrows F-F in FIG. 5.

Step 200

First, light-emitting diodes 10 (110, 210, and 310) are produced by the same method as that described Example 1.

Step 210

Then, the first light-emitting diode 110, the second light-emitting diode 210, and the third light-emitting diode 310 are pre-fixed to a light-emitting unit production substrate 53 to prepare light-emitting units each including a desired number of the first light-emitting diodes 110, a desired number of the second light-emitting diodes 210, and a desired number of the third light-emitting diodes 310, the first electrodes 114, 214, and 314 of the first light-emitting diode 110, the second light-emitting diode 210, and the third light-emitting diode 310 being connected to the sub-common electrode 43.

Step 210A

Specifically, the first light-emitting diodes 110 on a first support substrate are transferred to the fixing layer 34, the second light-emitting diodes 210 on a second support substrate are transferred to the fixing layer 34, and the third light-emitting diodes 310 on a third support substrate are transferred to the fixing layer 34. However, the order of transferring these light-emitting diodes is basically arbitrary. For the transferring operation, a first transfer substrate 31 provided with the fixed layer 34 is prepared. As described above, the fixed layer 34 has a two-layer structure including the insulating material layer 32 and the burying material layer 33 provided in that order from the first transfer substrate side. The insulating material layer 32 is formed of a polyimide resin, and the burying material layer 33 is formed of a photosensitive resin. A portion of the burying material layer 33 in which the first light-emitting diode 110, the second light-emitting diode 210, and the third light-emitting diode 310 are to be buried is not cured, and the other portions of the burying material layer 33 are cured.

Step 210A-(1)

Subsequently, first, similar to Example 1, a support substrate (pre-fixing substrate) 20 is bonded so that the extraction electrode 16 is in contact with the support substrate 20 (see FIG. 1B). After that, the light-emitting diode production substrate 19A is removed from the light-emitting diodes 10 (110, 210, and 310). Then, the first electrodes 14 (114, 214, and 314) which are the n-side electrodes are formed on the exposed first compound semiconductor layer 11. Specifically, the interface between the light-emitting diodes 10 (110, 210, and 310) (more specifically, the first compound semiconductor layer 11) and the light-emitting diode production substrate 19A is irradiated with an excimer laser through the light-emitting diode production substrate 19A. As a result, laser abrasion occurs, whereby the light-emitting diode production substrate 19A is separated from the light-emitting diodes 10 (110, 210, and 310) (see FIG. 8A). Thereafter, the first electrodes 14 (114, 214, and 314) which are the n-side electrodes are formed on the first compound semiconductor layer 11 by a lift-off method and a vacuum evaporation method. In this way, the structure shown in FIG. 8B is obtained. Thereafter, the light-emitting diodes 10 are separated from each other by performing etching. In this way, the structure shown in FIG. 8C is obtained.

Step 210A-(2)

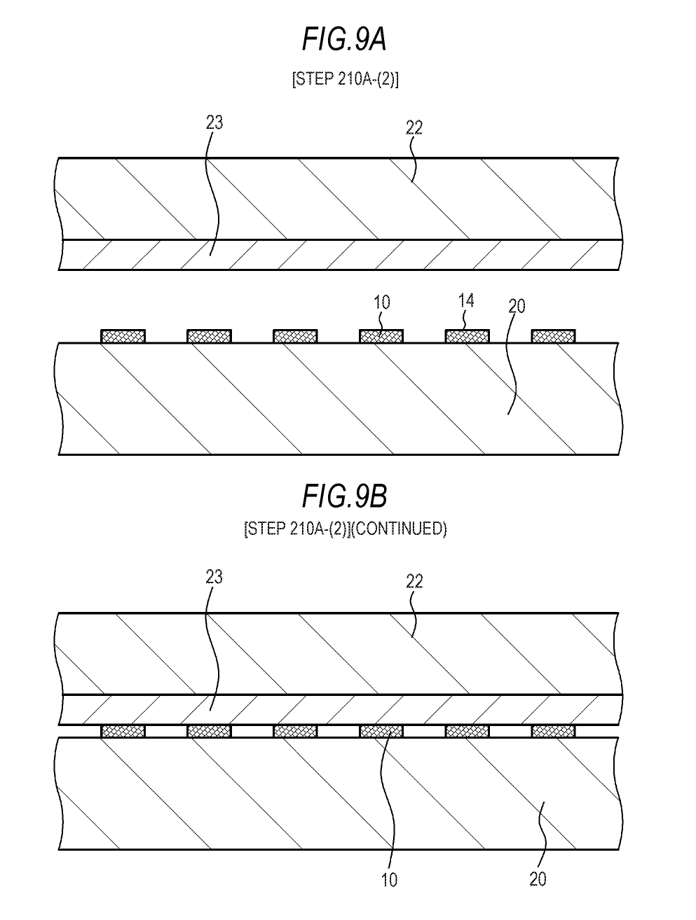

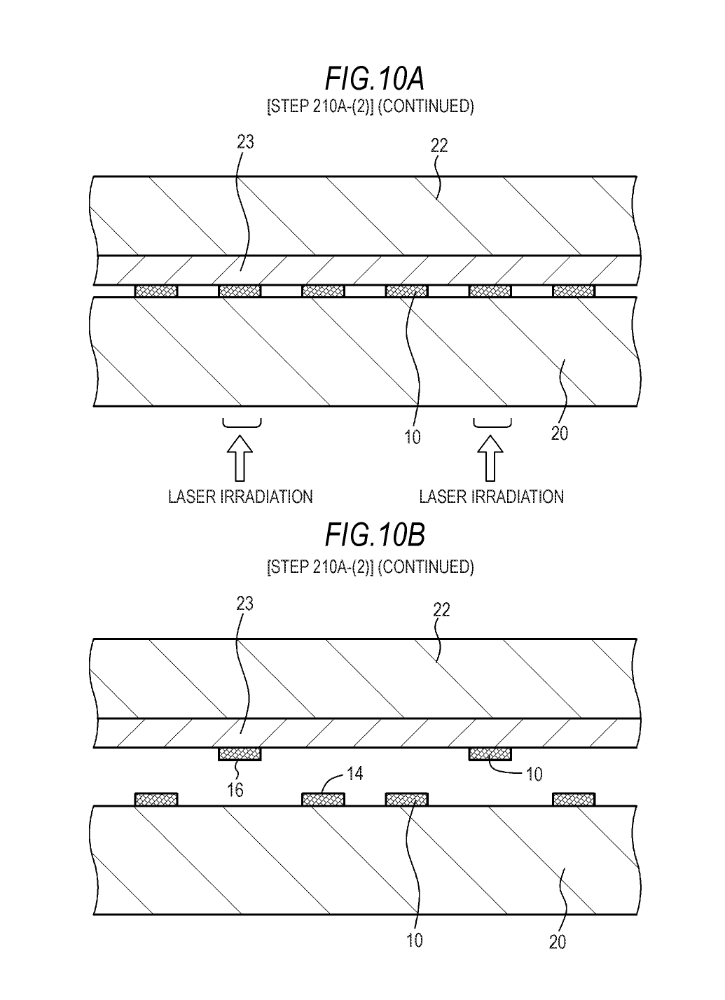

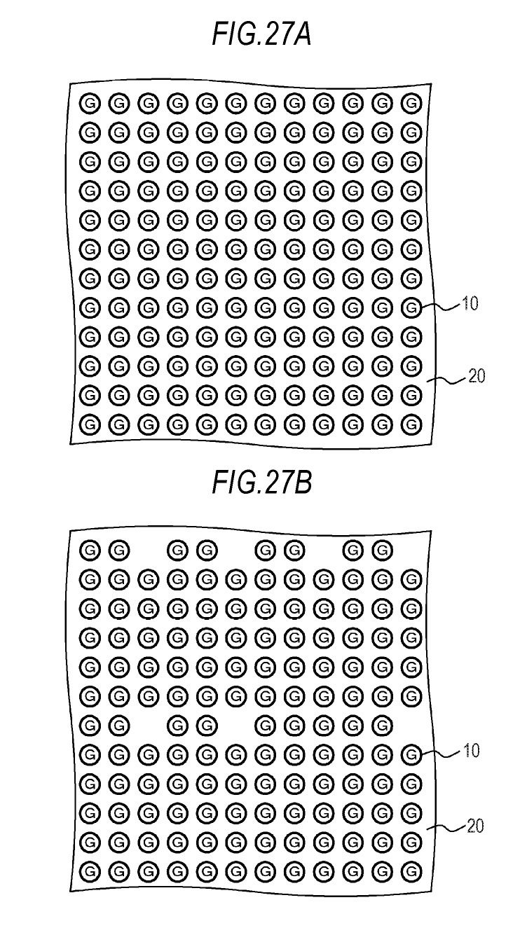

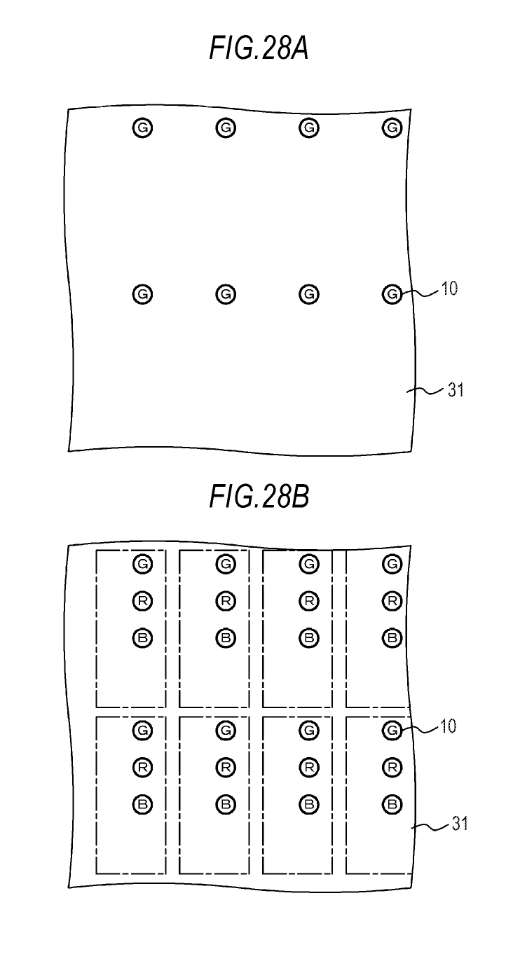

Next, desired light-emitting diodes 10 (110, 210, and 310) are transferred from the support substrate 20 to an intermediate substrate 22. That is to say, the light-emitting diodes 10 (110, 210, and 310) bonded to the support substrate 20 are attached to the intermediate substrate 22. Specifically, first, a slightly adhesive layer 23 formed on a surface of the intermediate substrate 22 formed of a glass substrate is pressed onto the light-emitting diodes 10 (110, 210, and 310) on the support substrate 20 on which the light-emitting diodes 10 are left in an array (two-dimensional matrix) as schematically shown in FIG. 27A (see FIGS. 9A and 9B). In FIGS. 27A, 27B, 28A, and 28B, a circle shown by “G” at the center represents the second light-emitting diode 210 which emits green light. In FIG. 28B, a circle shown by “R” at the center represents the first light-emitting diode 110 which emits red light, and a circle shown by “B” at the center represents the third light-emitting diode 310 which emits blue light. The slightly adhesive layer 23 is formed of, for example, silicone rubber. The intermediate substrate 22 is supported by a positioning device (not shown). The positional relationship between the intermediate substrate 22 and the back surface 20 is controlled by the operation of the positioning device. After that, the light-emitting diodes 10 (110, 210, and 310) to be mounted are irradiated with, for example, an excimer laser from the back side of the support substrate 20 (see FIG. 10A). As a result, laser abrasion occurs whereby the light-emitting diodes 10 (110, 210, and 310) irradiated with an excimer laser are separated from the support substrate 20. Thereafter, when the intermediate substrate 22 is separated from the light-emitting diodes 10, the light-emitting diodes 10 separated from the back surface 20 are attached to the slightly adhesive layer 23 (see FIG. 10B). FIG. 27B schematically shows the state of the support substrate 20 in which one of every six light-emitting diodes in the second direction is attached to the slightly adhesive layer 23, and one of every three light-emitting diodes in the first direction is attached to the slightly adhesive layer 23.

Then, the light-emitting diodes 10 (110, 210, and 310) are arranged (moved or transferred) on the burying material layer 33. Specifically, the light-emitting diodes 10 (110, 210, and 310) are arranged on the burying material layer 33 of the first transfer substrate 31 from the intermediate substrate 22 based on an alignment mark formed on the first transfer substrate 31. Since the light-emitting diodes 10 (110, 210, and 310) are weakly attached to the slightly adhesive layer 23, the light-emitting diodes 10 (110, 210, and 310) are left on the uncured burying material layer 33 when the intermediate substrate 22 is moved away from the first transfer substrate 31 in a state where the light-emitting diodes 10 (110, 210, and 310) are brought (pressed) into contact with the burying material layer 33. Furthermore, by burying the light-emitting diodes 10 (110, 210, and 310) deeply in the burying material layer 33 using a roller or the like, it is possible to fix (arrange) the light-emitting diodes 10 (110, 210, and 310) to the fixed layer 34. FIG. 28A schematically shows the state of the first transfer substrate 31.

For convenience sake, the method using such an intermediate substrate 22 is referred to as the “step transfer method.” When such a step transfer method is repeated a desired number of times, desired numbers of the light-emitting diodes 10 (110, 210, and 310) are attached to the slightly adhesive layer 23 in a two-dimensional matrix and are transferred to the first transfer substrate 31. Specifically, in Example 2, in one execution of the step transfer, 10800(=120×90) light-emitting diodes 10 (110, 210, and 310) are attached to the slightly adhesive layer 23 in a two-dimensional matrix and are transferred to the first transfer substrate 31. This operation is repeated 4×3 times. Furthermore, the transferring operation to the first transfer substrate 31 is performed for each of the light-emitting diodes 110, 210, and 310, and thus the transferring operation is performed 36 times (=4×3×3) in total. As a result, predetermined numbers of red light-emitting diodes, green light-emitting diodes, and blue light-emitting diodes can be mounted at predetermined distances and pitches on the first transfer substrate 31. The state of the first transfer substrate 31 is schematically shown in FIG. 28B. In FIG. 28B, each light-emitting unit is surrounded by the one-dot chain line. Finally, the light-emitting units are transferred and fixed to a display substrate 61 to produce a light-emitting diode display device including a plurality of light-emitting units which are arranged in the first direction and the second direction perpendicular to the first direction, i.e., arranged in a two-dimensional matrix. In this case, when 129600 (=480×270) light-emitting units are transferred to the display substrate 61 each time, by performing the transferring operation 16 times, it is possible to obtain a light-emitting diode display device including 1920×1080 light-emitting units.

Then, the uncured burying material layer 33 formed of a photosensitive resin in which the light-emitting diodes 10 (110, 210, and 310) have been arranged is irradiated with ultraviolet light to cure the photosensitive resin constituting the burying material layer 33. As a result, the light-emitting diodes 10 (110, 210, and 310) are fixed to the burying material layer 33 (refer to FIGS. 11A, 11B, and 11C). In this state, the first electrodes 14 (114, 214, and 314) of the light-emitting diodes 10 (110, 210, and 310) are exposed.

Step 210B

Next, the sub-common electrode 43 is formed, by a sputtering method and a lift-off method, over the first electrodes 114, 214, and 314 of a light-emitting diode group 110, 210, 310 which constitutes each light-emitting unit and the fixed layer 34, the light-emitting diode group including a desired number (in Example 2, N₁=1) of the first light-emitting diode 110, a desired number (in Example 2, N₂=1) of the second light-emitting diode 210, and a desired number (in Example 2, N₃=1) of the third light-emitting diode 310.

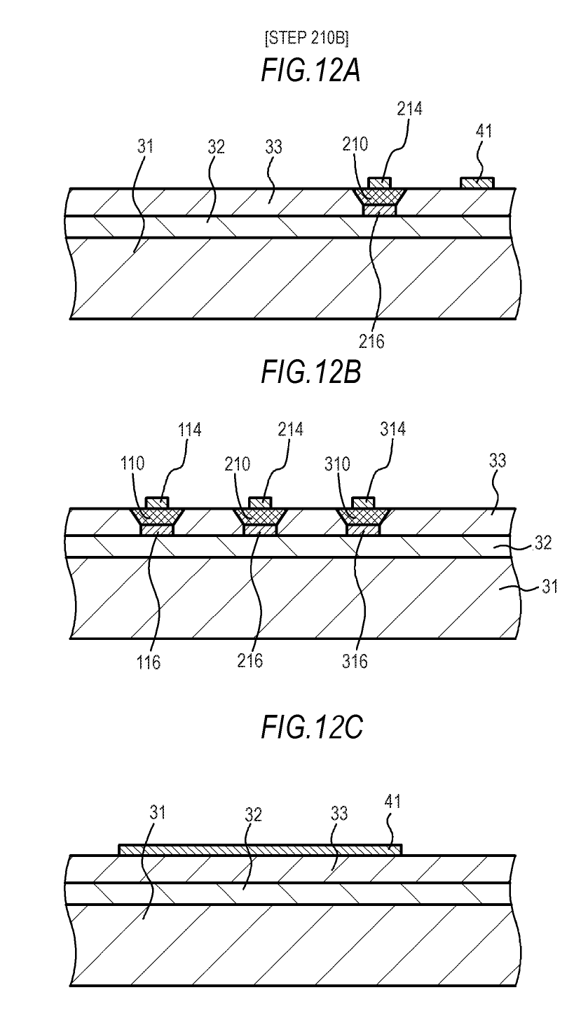

Specifically, first, a metal layer 41 is formed in a portion of the fixed layer 34 positioned apart from the first electrodes 114, 214, and 314 by a sputtering method and a lift-off method (see FIGS. 12A, 12B, and 12C).

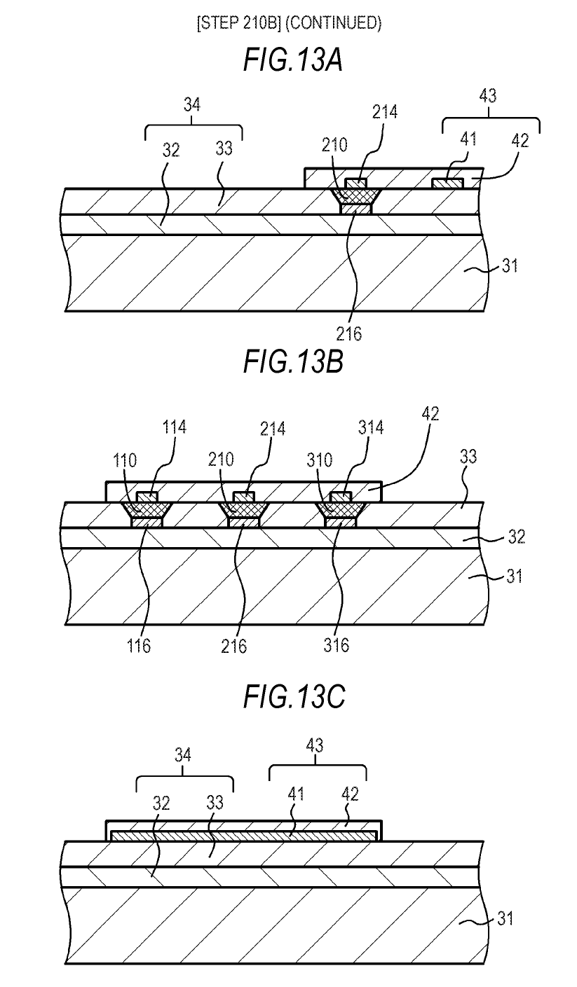

Subsequently, a light-transmitting electrode 42 is formed on the fixed layer 34 so as to extend from the metal layer 41 to the first electrodes 114, 214, and 314 by a sputtering method and a lift-off method (see FIGS. 13A, 13B, and 13C).

Step 210C

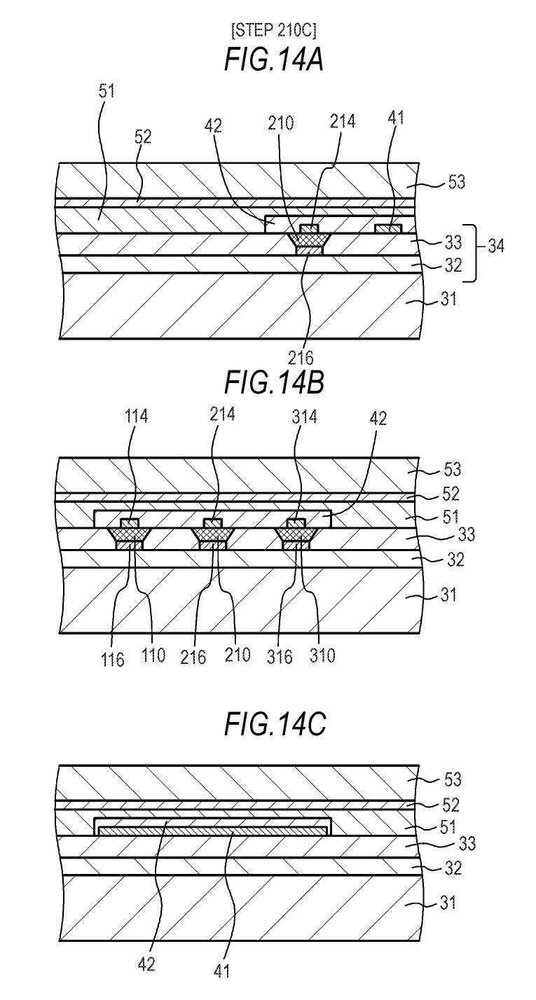

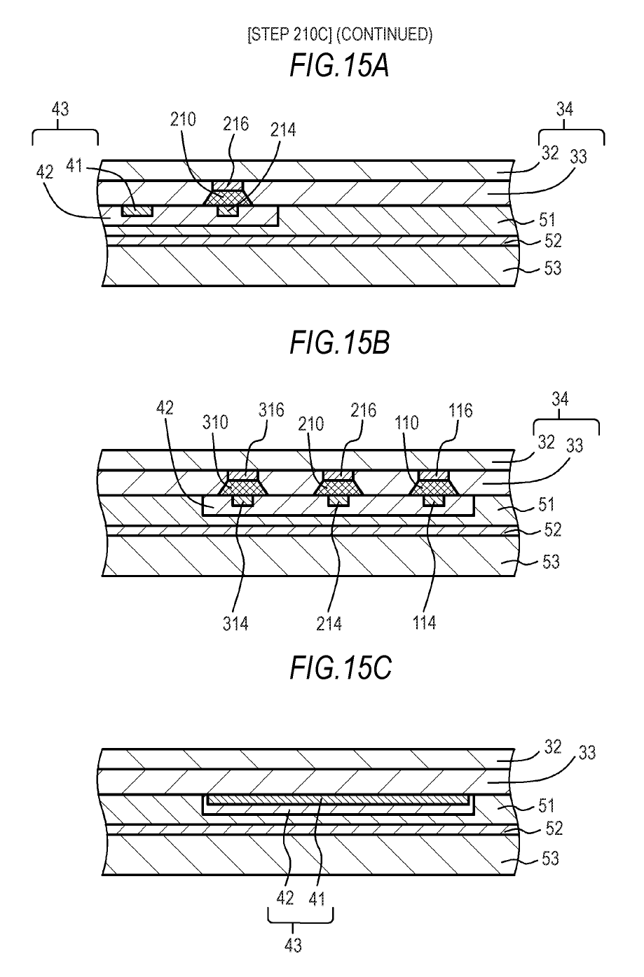

Then, the light-emitting diode group 110, 210, 310 which forms each light-emitting unit is bonded and pre-fixed to a light-emitting unit production substrate 53 via the fixed layer 34 and the sub-common electrode 43, and then the first transfer substrate 31 is removed. Specifically, the light-emitting unit production substrate 53 is prepared in which a laser separating layer 52 formed of a resin layer with a laser abrasion property, such as an epoxy resin or a polyimide resin, and a third insulating layer 51 formed of an epoxy resin or the like and functioning as an adhesive layer are formed. Then, the fixed layer 34 and the sub-common electrode 43 are bonded and pre-fixed to the third insulating layer 51 (see FIGS. 14A, 14B, and 14C). Thereafter, for example, an excimer laser is irradiated from the side of the first transfer substrate 31. As a result, laser abrasion occurs whereby the first transfer substrate 31 is separated from the insulating layer 32 (see FIGS. 15A, 15B, and 15C).

Step 210D

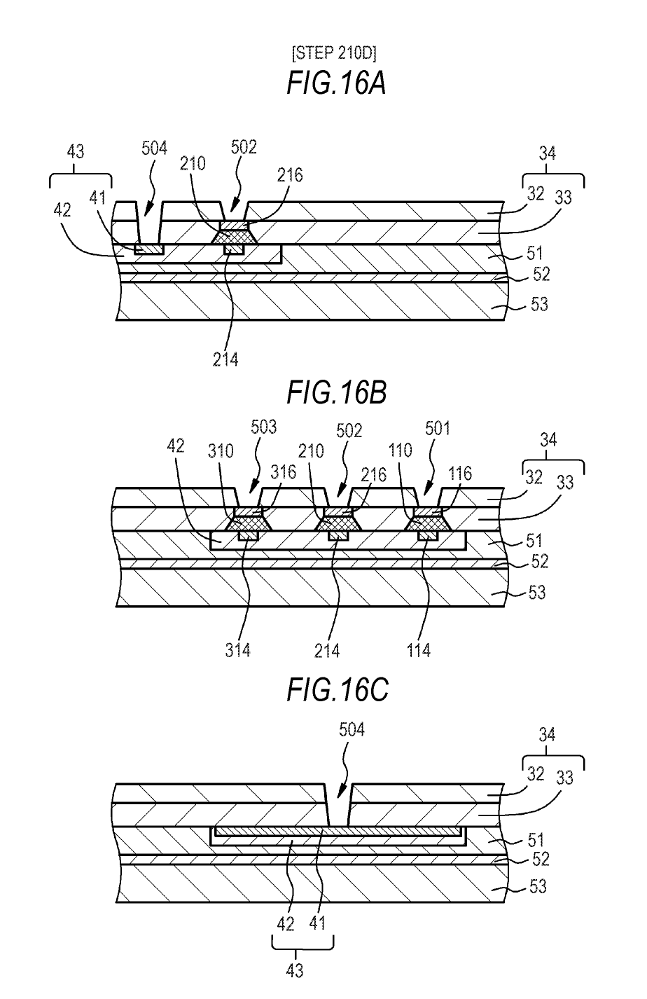

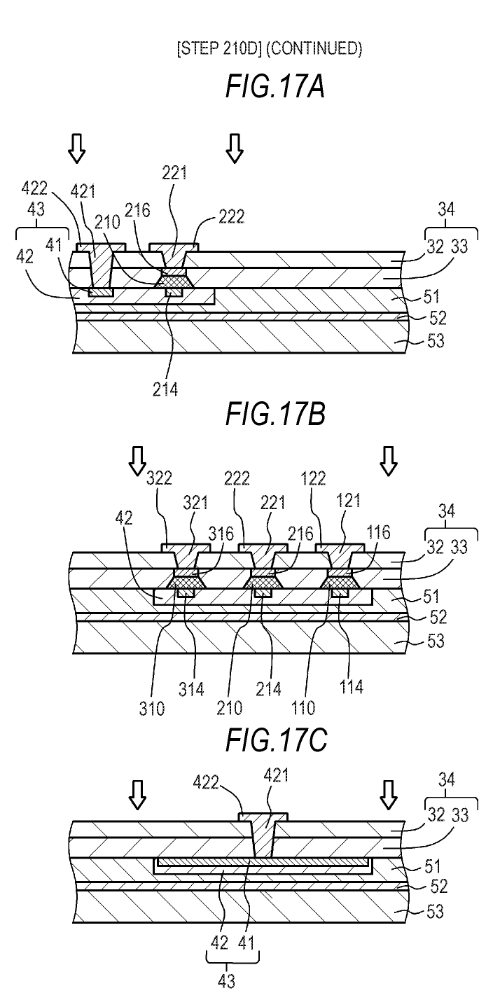

Next, the first contact hole portion 121 connected to the extraction electrode 116 of the first light-emitting diode 110 is formed in the fixed layer 34, and the first pad portion 122 is formed so as to extend from the first contact hole portion 121 to the fixed layer 34. In addition, the second contact hole portion 221 connected to the extraction electrode 216 of the second light-emitting diode 210 is formed in the fixed layer 34, and the second pad portion 222 is formed so as to extend from the second contact hole portion 221 to the fixed layer 34. Furthermore, the third contact hole portion 321 connected to the extraction electrode 316 of the third light-emitting diode 310 is formed in the fixed layer 34, and the third pad portion 322 is formed so as to extend from the third contact hole portion 321 to the fixed layer 34. Furthermore, the fourth contact hole portion 421 connected to the sub-common electrode 43 is formed in the fixed layer 34, and the fourth pad portion 422 is formed so as to extend from the fourth contact hole portion 421 to the fixed layer 34. In this way, the light-emitting unit is obtained. Specifically, opening portions 501, 502, 503, and 504 are provided in the insulating material layer 32 that is disposed above the extraction electrodes 116, 216, and 316 and the metal layer 41 by a lithographic technique and an etching technique. Then, a metal material layer is formed on the insulating material layer 32 including the inner portions of the opening regions 501, 502, 503, and 504 by a sputtering method. The metal material layer is subsequently patterned by a well-known lithographic technique and etching technique, whereby the first contact hole portion 121, the first pad portion 122, the second contact hole portion 221, the second pad portion 222, the third contact hole portion 321, the third pad portion 322, the fourth contact hole portion 421, and the fourth pad portion 422 are obtained (see FIGS. 16A, 16B and 16C and FIGS. 17A, 17B, and 17C).

Step 210E

Subsequently, the light-emitting units including the light-emitting diode groups 110, 210, and 310 are separated in the fixed layer 34 by a laser irradiation method. In FIGS. 17A, 17B, and 17C, portions irradiated with laser are shown by the empty arrows.

In Example 2, the arrangement pitch of the first light-emitting diodes 110 in the light-emitting diode display device or the electronic device is an integral multiple of the manufacturing pitch of the first light-emitting diodes 110 on the first support substrate. The arrangement pitch of the second light-emitting diodes 210 in the light-emitting diode display device or the electronic device is an integral multiple of the manufacturing pitch of the second light-emitting diodes 210 on the second support substrate. The arrangement pitch of the third light-emitting diodes 310 in the light-emitting diode display device or the electronic device is an integral multiple of the manufacturing pitch of the third light-emitting diodes 310 on the third support substrate. Specifically, the arrangement pitch of the first light-emitting diodes 110, 210, and 310 along the second direction in the light-emitting diode display device or the electronic device is 6 times the manufacturing pitch of the first light-emitting diodes 110, 210, and 310 on the support substrates. The arrangement pitch of the first light-emitting diodes 110, 210, and 310 along the first direction in the light-emitting diode display device or the electronic device is 3 times the manufacturing pitch of the first light-emitting diodes 110, 210, and 310 on the support substrates.

Step 220

Specifically, first, the light-emitting units are transferred from the light-emitting production substrate 53 to be fixed to a display substrate 61 to obtain a light-emitting diode display device or an electronic device in which a plurality of light-emitting units are arranged in the first direction and the second direction perpendicular to the first direction, i.e., arranged in a two-dimensional matrix.

Specifically, the display substrate 61 is prepared, on which the second insulating material layer 71 and the first, second, and third common electrodes 401, 402, and 403 extending along the second direction are formed. In this case, the first common electrode 401, the second common electrode 402, and the third common electrode 403 are covered with the second insulating material layer 71. The display substrate 61 is covered with a fourth insulating layer 62, and the first common electrode 401, the second common electrode 402, and the third common electrode 403 are formed on the fourth insulating layer 62. Moreover, the fourth insulating layer 62 and the first, second, and third common electrodes 401, 402, and 403 are covered with a fifth insulating layer 63 that functions as an adhesive layer. Furthermore, more specifically, the second insulating material layer 71 is formed on the fifth insulating layer 63. The second insulating material layer 71 is not formed in portions of the display substrate 61 to which the light-emitting units are to be fixed. Moreover, portions of the fifth insulating layer 63 to which the light-emitting units are to be fixed are not cured, the other portions of the fifth insulating layer 63 are cured. The display substrate 61 having such a configuration and structure can be formed by a well-known method.

Step 220A

Specifically, first, the light-emitting units are bonded to a second transfer substrate (not shown), and then the light-emitting unit production substrate 53 is removed. Specifically, substantially the same step as Step 210A-(2) may be performed. Specifically, an excimer laser, for example, is irradiated from the back side of the light-emitting unit production substrate 53. As a result, laser abrasion occurs whereby the light-emitting production substrate 53 is separated from the laser separation layer 52.

Step 220B

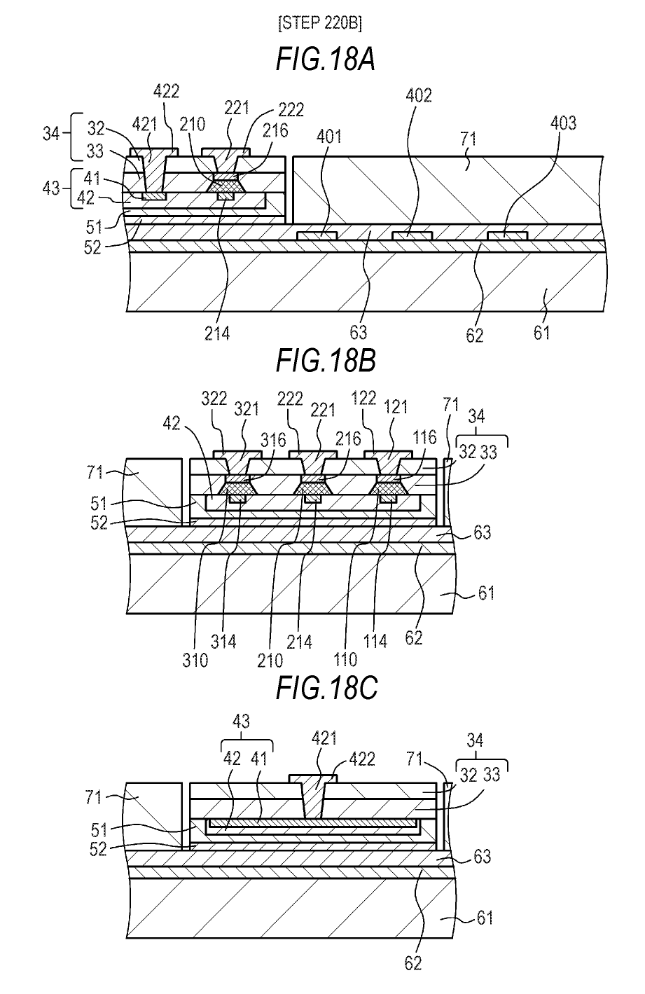

Next, the light-emitting units are arranged on the display substrate 61 so as to be surrounded by the second insulating material layer 71, and then the second transfer substrate is removed. Specifically, the light-emitting units and the fixed layer 34 around the units are arranged (moved or transferred) on the fifth insulating layer 63 that is exposed and surrounded by the second insulating material layer 71 (see FIGS. 18A, 18B, and 18C). More specifically, the light-emitting units and the fixed layer 34 around the units are moved from the second transfer substrate 31 to be arranged on the fifth insulating layer 63 that is exposed and surrounded by the second insulating material layer 71 based on alignment marks formed on the second transfer substrate. Since the light-emitting units and the fixed layer 34 around the units are weakly attached to the slightly adhesive layer (not shown) provided on the second transfer substrate, the light-emitting units and the fixed layer 34 around the units will be left on the fifth insulating layer 63 when the second transfer substrate is moved away from the display substrate 61 in a state where the light-emitting units and the fixed layer 34 around the units are brought (pressed) into contact with the fifth insulating layer 63. Furthermore, by burying the light-emitting units and the fixed layer 34 around the units deeply in the fifth insulating layer 63 using a roller or the like, it is possible to fix (arrange) the light-emitting units and the fixed layer 34 around the units to the fifth insulating layer 63. After all light-emitting units are completely arranged, the fifth insulating layer 63 is cured.

Step 220C

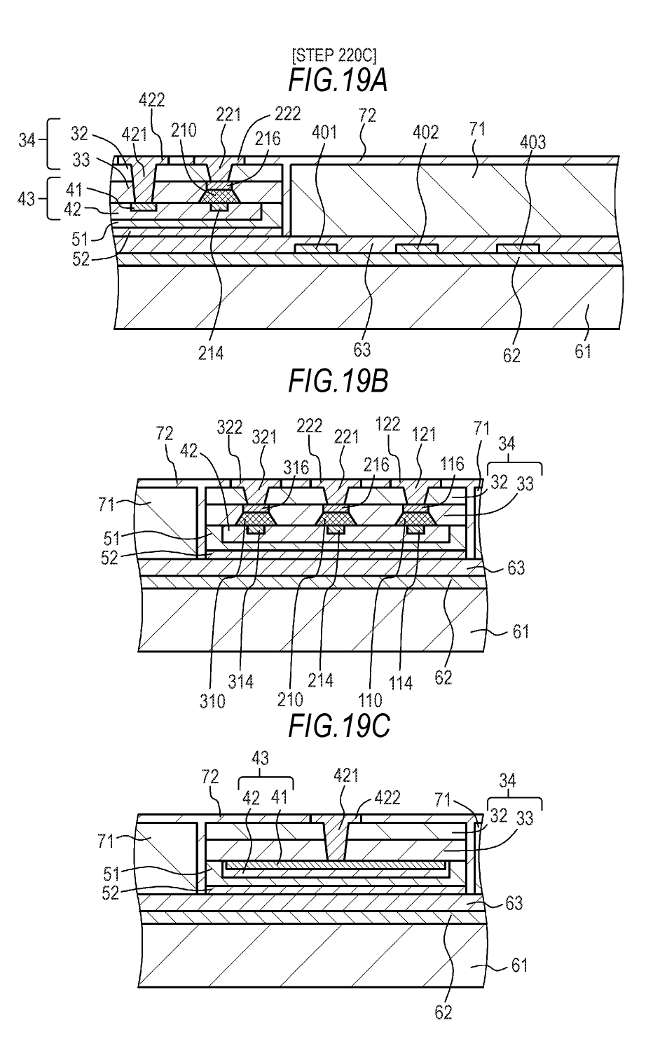

Then, a planarization layer 72 formed of an insulating resin is formed over the entire surface by a spin coating method to obtain a flat planarization layer 72. In this way, a structure shown in FIGS. 19A, 19B, and 19C is obtained.

Step 220D

Next, the second A-connection portion 124 for electrically connecting the first pad portion 122 and the first common electrode 401 is formed so as to extend from the fixed layer 34 to the second insulating material layer 71. In addition, the second B-connection portion 224 for electrically connecting the second pad portion 222 and the second common electrode 402 is formed so as to extend from the fixed layer 34 to the second insulating material layer 71. Furthermore, the second C-connection portion 324 for electrically connecting the third pad portion 322 and the third common electrode 403 is formed so as to extend from the fixed layer 34 to the second insulating material layer 71. Furthermore, the fourth common electrode 404 is formed on the second insulating material layer 71, and the third connection portion 424 for electrically connecting the fourth pad portion 422 and the fourth common electrode 404 is formed so as to extend from the fixed layer 34 to the second insulating material layer 71.

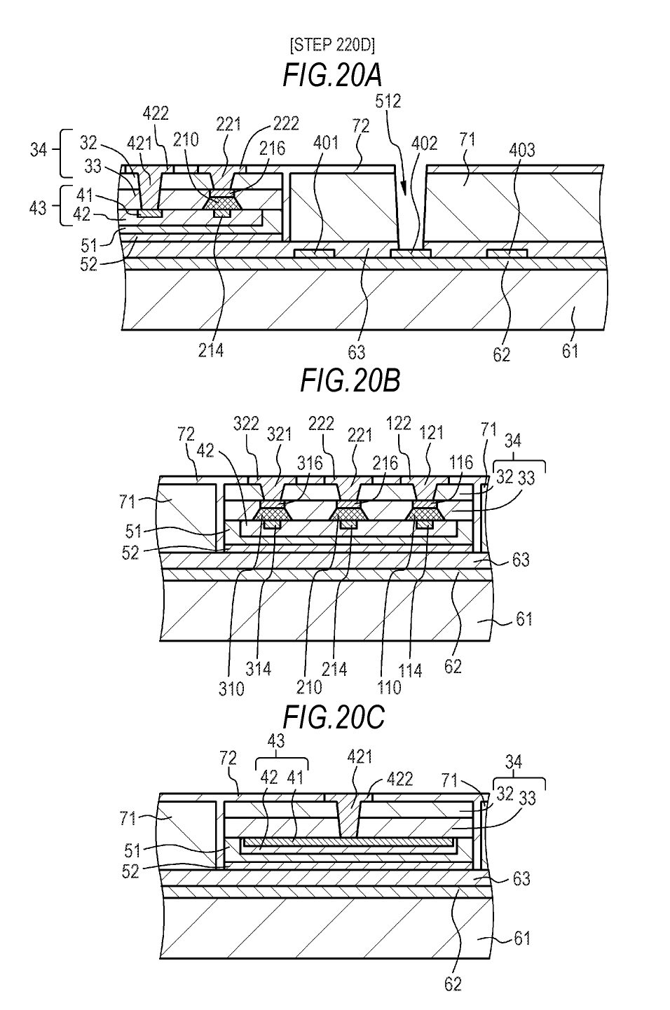

Specifically, an opening region (in the example shown in FIGS. 20A to 20C, an opening region 512) is formed in the planarizing layer 72, the second insulating material layer 71, and the fifth insulating layer 63 by a lithographic technique and an etching technique. Then, the second A-connection portion 124, the second B-connection portion 224, the second C-connection portion 324, and the third connection portion 424 are formed by a sputtering method, a lithographic technique, and an etching technique. In this way, a structure shown in FIGS. 6A, 6B, and 6C and FIGS. 7A, 7B, and 7C is obtained.

In Example 2 or Example 3 described later, a plurality of light-emitting units in each of which the first electrodes 114, 214, and 314 of the first light-emitting diode 110, the second light-emitting diode 210, and the third light-emitting diode 310 are connected to the sub-common electrode 43 are transferred to the display substrate 61. Furthermore, the light-emitting units are fixed to the display substrate 61 with the second electrodes facing upward. Therefore, in a subsequent step, the second electrodes of the first light-emitting diode 110, the second light-emitting diode 210, and the third light-emitting diode 310 are easily extended to the common electrodes (common wirings) 401, 402, and 403 of the second electrodes, respectively, and the first electrodes 114, 214, and 314 are easily extended to the first wiring (the fourth common electrode 404). As a result, the number of micro-processes can be reduced, and the process for manufacturing a light-emitting diode display device or an electronic device can be simplified. In addition, since the area of the light-emitting diodes 110, 210, and 310 in one pixel is small, and the light-emitting diodes 110, 210, and 310 are arranged to be close to each other, it is possible to prevent so-called color breakup.

### Example 3

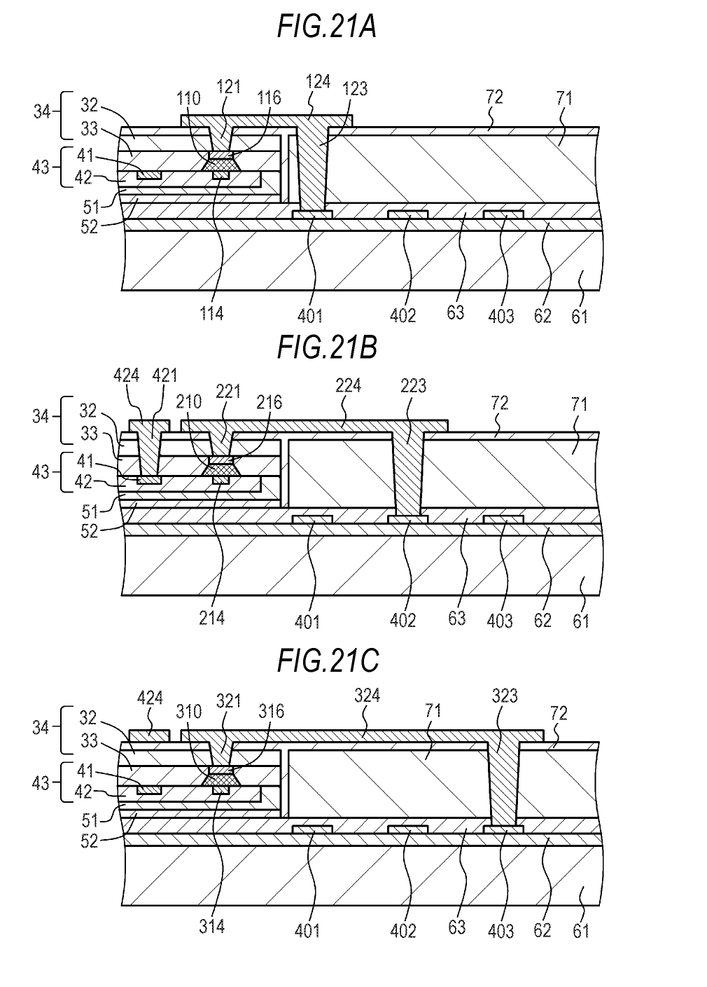

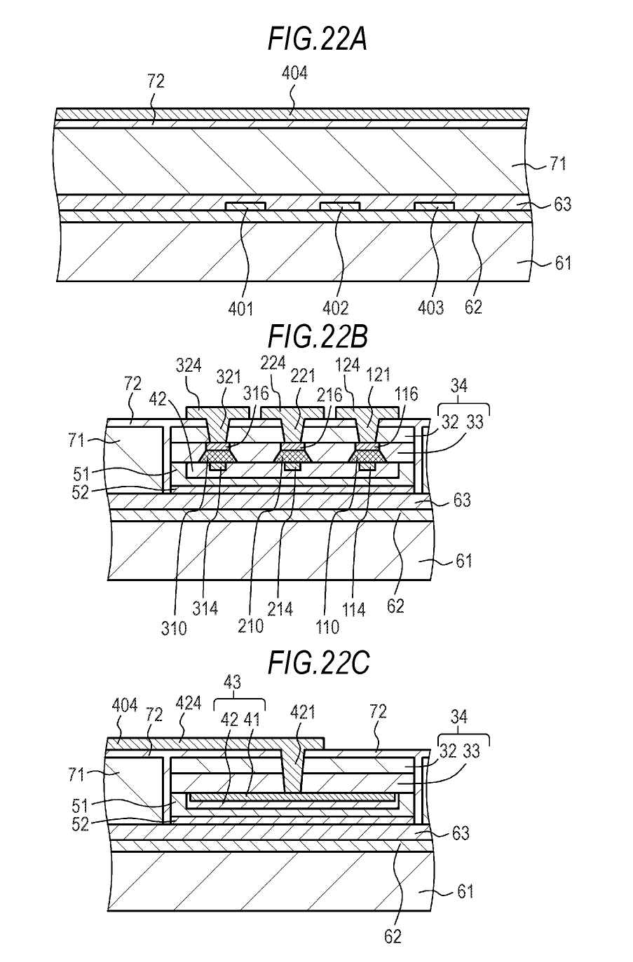

Example 3 is a modification of Example 2. The configuration and structure of the light-emitting diode display device or the electronic device which is shown in the schematic partial cross-sectional views of FIGS. 21A, 21B, and 21C and FIGS. 22A, 22B, and 22C and which is obtained by the method of manufacturing the light-emitting diode display device or the electronic device according to Example 3 are substantially the same as those of the light-emitting diode display device or the electronic device according to Example 2, except that the first, second, third, and fourth pad portions are not formed. Therefore, detailed description thereof will be omitted. FIGS. 21A, 21B, 21C, 22A, 22B, and 22C are schematic partial cross-sectional views equivalent to those taken along the arrows A-A, B-B, C-C, D-D, E-E, and F-F in FIG. 5, respectively.

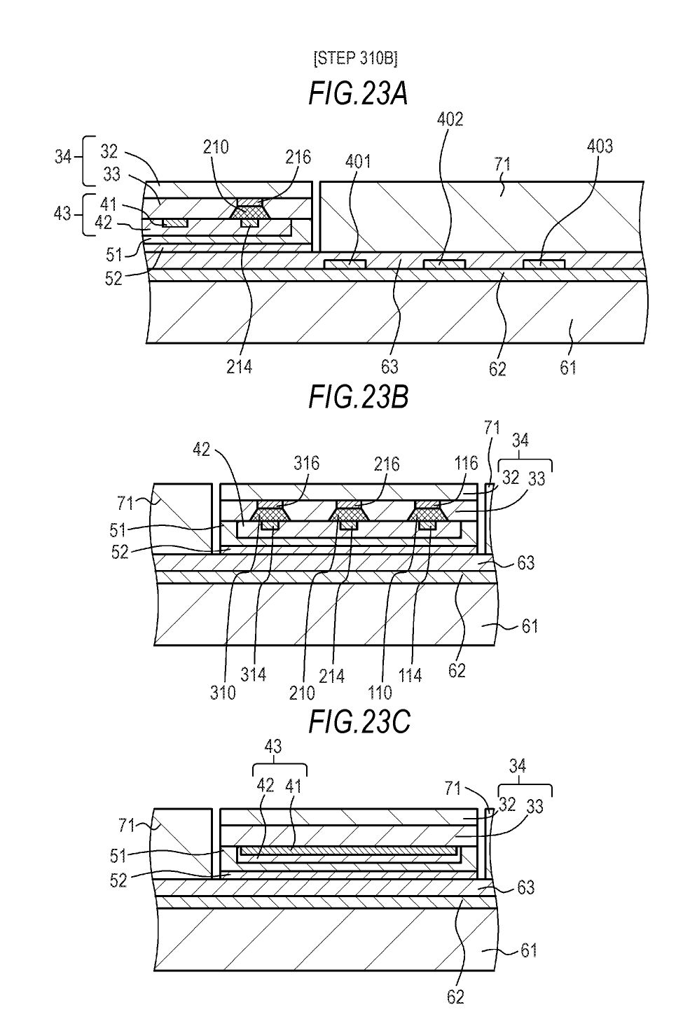

Hereinafter, a method of manufacturing a light-emitting diode display device or an electronic device according to Example 3 will be described below with reference to FIGS. 23A, 23B, 23C, 24A, 24B, 24C, 25A, 25B, and 25C. In the drawings, FIGS. 23A, 24A, and 25A are schematic partial cross-sectional views equivalent to those taken along the arrows B-B in FIG. 5. FIGS. 23B, 24B, and 25B are schematic partial cross-sectional views equivalent to those taken along the arrows E-E in FIG. 5. FIGS. 23C, 24C, and 25C are schematic partial cross-sectional views equivalent to those taken along the arrows F-F in FIG. 5.

Step 300

First, light-emitting diodes 10 (110, 210, and 310) are produced by the same method as in Step 200 of Example 2. Next, the same steps as Step 210A and Step 210B of Example 2 are performed, and then the same step as Step 210C of Example 2 is performed to bond and pre-fix light-emitting diode groups 110, 210, and 310, which constitute light-emitting units, to a light-emitting unit production substrate 53 via a fixed layer 34 and a sub-common electrode 43, thereby producing light-emitting units. Then, the first transfer substrate 31 is removed. Then, the same step as Step 210E of Example 2 is performed to separate the light-emitting units in the fixed layer 34.

Step 310

Similar to Example 2, a display substrate 61 is prepared, on which a second insulating material layer 71 and first, second, and third common electrodes 401, 402, and 403 covered with the second insulating material layer 71 and extending along the first direction are formed.

Step 310A

The light-emitting units are bonded to a second transfer substrate (not shown) by the same step as Step 220A of Example 2, and then the light-emitting unit production substrate 53 is removed.

Step 310B

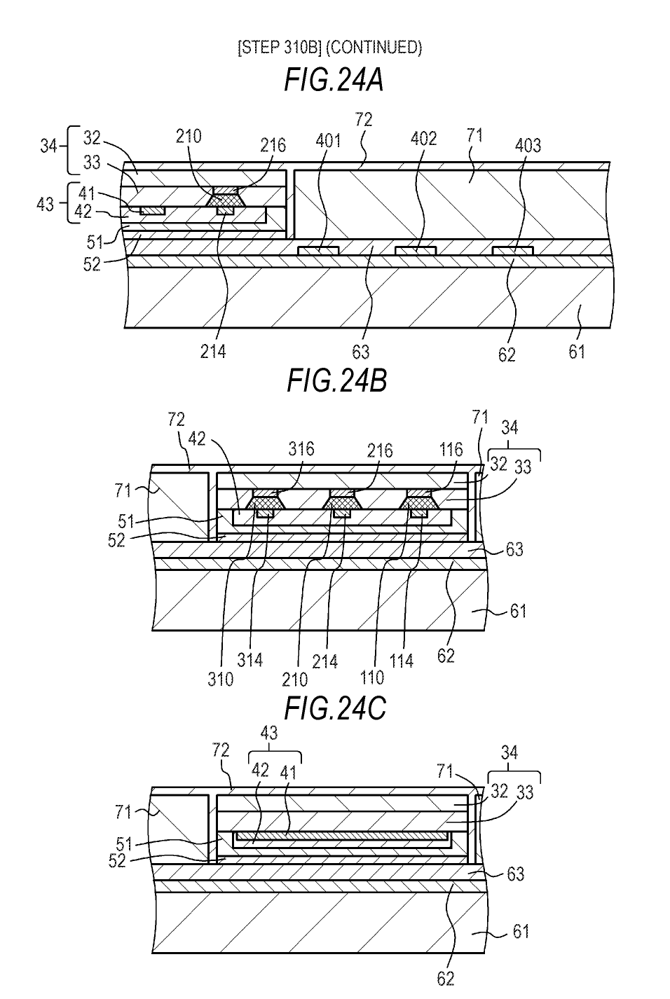

Next, the light-emitting units are arranged on the display substrate 61 so as to be surrounded by the second insulating layer 71 by the same method as in Step 220B and Step 220C of Example 2, and then the second transfer substrate is removed (see FIGS. 23A, 23B, 23C, 24A, 24B, and 24C).

Step 310C

Then, first contact hole portions 121 for electrically connecting the extraction electrodes 116 of the first light-emitting diodes 110 and the first common electrode 401 are formed in the fixed layer 34, and first connection portions 124 are formed so as to extend from the fixed layer 34 to the planarizing layer 72 and the second insulating material layer 71. In addition, second contact hole portions 221 for electrically connecting the extraction electrodes 216 of the second light-emitting diodes 210 and the second common electrode 402 are formed in the fixed layer 34, and second connection portions 224 are formed so as to extend from the fixed layer 34 to the planarizing layer 72 and the second insulating material layer 71. Furthermore, third contact hole portions 321 for electrically connecting the extraction electrodes 316 of the third light-emitting diodes 310 and the third common electrode 403 are formed in the fixed layer 34, and third connection portions 324 are formed so as to extend from the fixed layer 34 to the planarizing layer 72 and the second insulating material layer 71. Furthermore, a fourth common electrode 404 is formed on the second insulating material layer 71, fourth contact hole portions 421 for electrically connecting the sub-common electrode 43 and the fourth common electrode 404 are formed in the fixed layer 34, and fourth connection portions 424 are formed so as to extend from the fixed layer 34 to the planarizing layer 72 and the second insulating material layer 71.

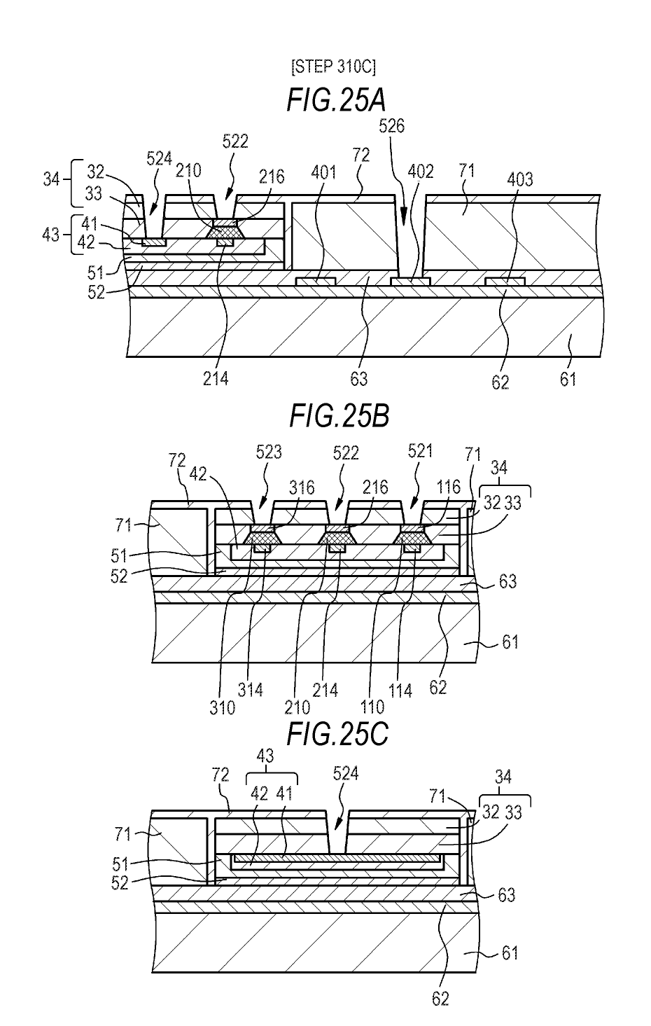

Specifically, opening regions 521, 522, 523, and 524 are formed in the planarizing layer 72, the second insulating material layer 71, and an insulating layer 32 so as to be disposed above the extraction electrodes 116, 216, and 316 and the metal layer 41 by a well-known lithographic technique and etching technique. In addition, opening regions are provided in the planarizing layer 72, the second insulating material layer 71, and the insulating layer 32 so as to be disposed above the first, second, third, and fourth common electrodes 401, 402, 403, and 404 (see FIGS. 25A, 25B, and 25C). FIG. 25A shows only an opening region 526. Then, a metal material layer is formed on the insulating layer 32 including the inner portions of the apertures 521, 522, 523, 524, and 526 by a sputtering method. The metal material layer is subsequently patterned by a well-known lithographic technique and etching technique, whereby the first contact hole portion 121, the second contact hole portion 221, the third contact hole portion 321, the fourth contact hole portion 421, the second A-connection portion 124, the second B-connection portion 224, the second C-connection portion 324, and the third connection portion 424 are obtained (see FIGS. 21A, 21B, 21C, 22A, 22B, and 22C).

Although the present application has been described above based on the preferred embodiments, the present application is not limited to these embodiments. The configurations and structures of the semiconductor light-emitting devices (light-emitting diodes) and the light-emitting diode display device and the electronic device including the light-emitting diodes, which are described in the embodiments, are only examples, and the constituent members and materials, and the like are also examples. Thus, the configurations and structures, and the constituent members and materials, and the like may be appropriately changed. The numerical values, materials, configurations, structures, shapes, substrates, raw materials, and processes described in the embodiments are given as examples only. If necessary, numerical values, materials, configurations, structures, shapes, substrates, raw materials, processes, and the like that are different from those used in the embodiments can be used. The planar shape of the opening portion formed in the insulating layer is not limited to rectangular but may be circular, if necessary.

Although, in the embodiments, the sub-common electrode 43 includes the metal layer 41 and the light-transmitting electrode 42, alternatively the sub-common electrode 43 may include only a metal layer or an alloy layer as long as light emission from the light-emitting diodes is not inhibited. According to circumferences, the first electrodes 114, 214, and 314 may be formed, for example, after Step 210A-(2) or in Step 210B of Example 2. In each of the light-emitting diodes, the lamination order of the compound semiconductor layers may be reversed. That is to say, although in the embodiments, the first conductivity type is the n type and the second conductivity type is the p type, conversely, the first conductivity type may be the p type and the second conductivity type may be the n type.

As the light-emitting diodes constituting each light-emitting unit, fourth light-emitting diodes, fifth light-emitting diodes, and the like may be further added to the first, second, and third light-emitting diodes. Examples of such a case include a light-emitting unit further including subpixels which emit white light so as to improve luminance, a light-emitting unit further including subpixels which emit complementary color light so as to extend a color reproduction range, a light-emitting unit further including subpixels which emit yellow light so as to extend a color reproduction range, and a light-emitting unit further including subpixels which emit yellow and cyan light so as to extend a color reproduction range. In these cases, the first electrodes of fourth light-emitting diodes, fifth light-emitting diodes, and the like may be connected to the sub-common electrodes.

The image display device (light-emitting diode display device) may be applied to not only color-display fiat-screen direct-viewing-type image display devices such as television receivers and computer terminals but also image display devices of a type in which an image is projected on the human retina, and projection-type image display devices. In these image display devices, for example, a field sequential driving system may be used, in which an image is display by time sharing control of emission/non-emission states of the first, second, and third light-emitting diodes. However, the driving system is not limited to this.

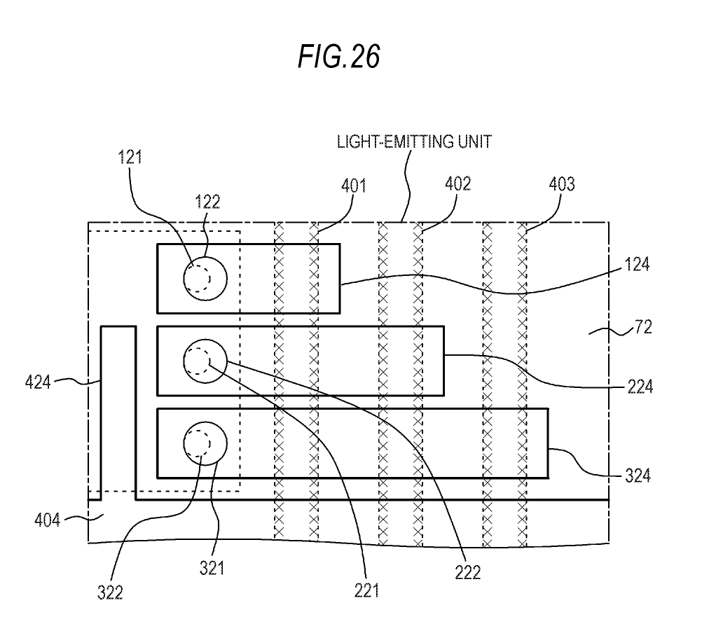

FIG. 26 is a schematic plan view showing one light-emitting unit according to a modified example of the light-emitting diode display device according to Example 2. In this modified example, the center of a first pad portion 122 (shown by the thin solid line in FIG. 26) which closes a first contact hole portion 121 (shown by the dotted line in FIG. 26) does not coincide with the center of the first contact hole portion 121, but the center of the first pad portion 122 is offset towards the first common wiring 401. In addition, the center of a second pad portion 222 (shown by the thin solid line in FIG. 26) which closes a second contact hole portion 221 (shown by the dotted line in FIG. 26) does not coincide with the center of the second contact hole portion 221, but the center of the second pad portion 222 is offset towards the second common wiring 402. Furthermore, the center of a third pad portion 322 (shown by the thin solid line in FIG. 26) which closes a third contact hole portion 321 (shown by the dotted line in FIG. 26) does not coincide with the center of the third contact hole portion 321, but the center of the third pad portion 322 is offset towards the third common wiring 403. In this configuration, for example, when the first, second, and third connection portions 124, 224, and 324 are formed, an allowance can be obtained for the distances between these connection portions 124, 224, and 324 and the fourth connection portion 424. Therefore, short-circuiting can be certainly prevented from occurring between these connection portions 124, 224, and 324 and the fourth connection portion 424.

According to the structure of the electronic device, the first wiring may be formed by a common wiring (common electrode), and the second wiring may have the same structure as the first or second wiring described in Example 2. Alternatively/additionally, the first wiring may have the same structure as the first or second wiring described in Example 2, and the second wiring may be formed by a common wiring (common electrode). Alternatively/additionally, the first wiring may be formed by a common wiring (common electrode), and the second wiring may also be formed by a common wiring (common electrode). In addition, the common wiring may be formed of a single sheet, or a plurality of sheets or strips in accordance with the structure of an electronic device. When the semiconductor light-emitting devices (light-emitting diodes) are AC-driven, semiconductor light-emitting devices (light-emitting diodes) in which a first connection portion is in contact with a first wiring and a second connection portion is in contact with a second wiring and semiconductor light-emitting devices (light-emitting diodes) in which a second connection portion is in contact with a first wiring and a first connection portion is in contact with a second wiring may be mixed. In the semiconductor light-emitting devices (light-emitting diodes) in which a second connection portion is in contact with a first wiring and a first connection portion is in contact with a second wiring, the second connection portion that is in contact with the first wiring would serve as a “first connection portion” and the first connection portion that is in contact with the second wiring would serve as a “second connection portion.”

It should be understood that various changes and modifications to the presently preferred embodiments described herein will be apparent to those skilled in the art. Such changes and modifications can be made without departing from the spirit and scope and without diminishing its intended advantages. It is therefore intended that such changes and modifications be covered by the appended claims.

1. A method of manufacturing a semiconductor light-emitting device assembly, comprising:
providing a plurality of light-emitting device portions on a light-emitting device production substrate so as to be separated from each other, each of the plurality of light-emitting device portions including a laminated structure, in which a first compound semiconductor layer having a first conductivity type, an active layer, and a second compound semiconductor layer having a second conductivity type different from the first conductivity type are sequentially laminated, and a second electrode provided on the second compound semiconductor layer;
forming an insulating layer on an entire surface thereof so as to have an opening portion in which a top central portion of the second electrode of each light-emitting device portion is exposed;
providing an extraction electrode to each light-emitting device portion so as to be patterned to extend from a top surface of the second electrode exposed to a bottom portion of the opening portion to the insulating layer; and
forming an adhesive layer so as to cover an entire surface thereof and attaching a support substrate using the adhesive layer,
the adhesive layer in which a portion of the extraction electrode is exposed is directly formed on the extraction electrode.

2. The method of manufacturing the semiconductor light-emitting device assembly according to claim 1, wherein a planar shape of the opening portion of the insulating layer is rectangular.

3. The method of manufacturing the semiconductor light-emitting device assembly according to claim 1, the patterned extraction electrode is provided to each light-emitting device portion by forming an extraction electrode layer on the insulating layer so as to extend from the top surface of the second electrode exposed to the bottom portion of the opening portion by a physical vapor deposition method, and then patterning the extraction electrode layer.

4. The method of manufacturing the semiconductor light-emitting device assembly according to claim 3, wherein an average thickness of the extraction electrode on the top surface of the second electrode is 0.1 μm to 1 μm.

5. The method of manufacturing the semiconductor light-emitting device assembly according to claim 1, wherein a maximum thickness tmax of the adhesive layer on an outer peripheral portion of each light-emitting device portion is 1.5 μm or less.

6. A semiconductor light-emitting device comprising:
a light-emitting device portion including a laminated structure, in which a first compound semiconductor layer having a first conductivity type, an active layer, and a second compound semiconductor layer having a second conductivity type different from the first conductivity type are sequentially laminated, and a second electrode provided on the second compound semiconductor layer;
an insulating layer that covers a side surface of the light-emitting device portion and a top peripheral portion of the second compound semiconductor layer and has an opening portion in which a top central portion of the second electrode is exposed;
an extraction electrode that is formed on the insulating layer so as to extend from the exposed top surface of the second electrode to the insulating layer; and
a first electrode that is electrically connected to the first compound semiconductor layer,
wherein a second insulating layer formed of an adhesive is directly formed on a portion of the extraction electrode, and the second insulating layer is not formed on the remaining portions of the extraction electrode.

7. The semiconductor light-emitting device according to claim 6, wherein a planar shape of the second compound semiconductor layer and a planar shape of the opening portion of the insulating layer are rectangular.

8. The semiconductor light-emitting device according to claim 6, wherein an average thickness of the extraction electrode on the top surface of the second electrode is 0.1 μm to 1 μm.

9. The semiconductor light-emitting device according to claim 6, wherein a maximum thickness tmax of the second insulating layer on an outer peripheral portion thereof is 1.5 μm or less.

10. A semiconductor light-emitting device comprising:
a light-emitting device portion including a laminated structure, in which a first compound semiconductor layer having a first conductivity type, an active layer, and a second compound semiconductor layer having a second conductivity type different from the first conductivity type are sequentially laminated, and a second electrode provided on the second compound semiconductor layer;
an insulating layer that covers a side surface of the light-emitting device portion and a top peripheral portion of the second compound semiconductor layer and has an opening portion in which a top central portion of the second electrode is exposed;
an extraction electrode that is formed on the insulating layer so as to extend from the exposed top surface of the second electrode to the insulating layer; and
a first electrode that is electrically connected to the first compound semiconductor layer,
wherein a planar shape of the second compound semiconductor layer and a planar shape of the opening portion of the insulating layer are rectangular.

11. An electronic device comprising:
a plurality of first wirings extending in a first direction;
a plurality of second wirings extending in a second direction different from the first direction; and
a plurality of semiconductor light-emitting devices each having a first connection portion and a second connection portion, the first connection portion being electrically connected to the first wirings, the second connection portion being electrically connected to the second wirings,
wherein each of the semiconductor light-emitting devices includes;
a light-emitting device portion including a laminated structure, in which a first compound semiconductor layer having a first conductivity type, an active layer, and a second compound semiconductor layer having a second conductivity type different from the first conductivity type are sequentially laminated, and a second electrode provided on the second compound semiconductor layer,
an insulating layer that covers a side surface of the light-emitting device portion and a top peripheral portion of the second compound semiconductor layer and has an opening portion in which a top central portion of the second electrode is exposed,
an extraction electrode that is formed on the insulating layer so as to extend from the exposed top surface of the second electrode to the insulating layer, and
a first electrode that is electrically connected to the first compound semiconductor layer,
the extraction electrode is electrically connected to the second connection portion or forms the second connection portion,
the first electrode is electrically connected to the first connection portion or forms the first connection portion, and
a second insulating layer formed of an adhesive is directly formed on a portion of the extraction electrode but is not formed on the remaining portions of the extraction electrode.

12. An electronic device comprising:
a plurality of first wirings extending in a first direction;
a plurality of second wirings extending in a second direction different from the first direction; and
a plurality of semiconductor light-emitting device each having a first connection portion and a second connection portion, the first connection portion being electrically connected to the first wirings, the second connection portion being electrically connected to the second wirings,
wherein each of the semiconductor light-emitting devices includes;
a light-emitting device portion including a laminated structure, in which a first compound semiconductor layer having a first conductivity type, an active layer, and a second compound semiconductor layer having a second conductivity type different from the first conductivity type are sequentially laminated, and a second electrode provided on the second compound semiconductor layer,
an insulating layer that covers a side surface of the light-emitting device portion and a top peripheral portion of the second compound semiconductor layer and has an opening portion in which a top central portion of the second electrode is exposed,
an extraction electrode that is formed on the insulating layer so as to extend from the exposed top surface of the second electrode to the insulating layer, and
a first electrode that is electrically connected to the first compound semiconductor layer,
the extraction electrode is electrically connected to the second connection portion or forms the second connection portion,
the first electrode is electrically connected to the first connection portion or forms the first connection portion, and
a planar shape of the second compound semiconductor layer and a planar shape of the opening portion of the insulating layer are rectangular.

13. An image display device comprising:
a plurality of first wirings extending in a first direction;
a plurality of second wirings extending in a second direction different from the first direction; and
a plurality of semiconductor light-emitting devices each having a first connection portion and a second connection portion, the first connection portion being electrically connected to the first wirings, the second connection portion being electrically connected to the second wirings,
wherein each of the semiconductor light-emitting devices includes;
a light-emitting device portion including a laminated structure, in which a first compound semiconductor layer having a first conductivity type, an active layer, and a second compound semiconductor layer having a second conductivity type different from the first conductivity type are sequentially laminated, and a second electrode provided on the second compound semiconductor layer,
an insulating layer that covers a side surface of the light-emitting device portion and a top peripheral portion of the second compound semiconductor layer and has an opening portion in which a top central portion of the second electrode is exposed,
an extraction electrode that is formed on the insulating layer so as to extend from the exposed top surface of the second electrode to the insulating layer, and
a first electrode that is electrically connected to the first compound semiconductor layer,
the extraction electrode is electrically connected to the second connection portion or forms the second connection portion,
the first electrode is electrically connected to the first connection portion or forms the first connection portion,
a second insulating layer formed of an adhesive is directly formed on a portion of the extraction electrode but is not formed on the remaining portions of the extraction electrode.

14. An image display device comprising:
a plurality of first wirings extending in a first direction;
a plurality of second wirings extending in a second direction different from the first direction; and
a plurality of semiconductor light-emitting devices each having a first connection portion and a second connection portion, the first connection portion being electrically connected to the first wirings, the second connection portion being electrically connected to the second wirings,
wherein each of the semiconductor light-emitting devices includes;
a light-emitting device portion including a laminated structure, in which a first compound semiconductor layer having a first conductivity type, an active layer, and a second compound semiconductor layer having a second conductivity type different from the first conductivity type are sequentially laminated, and a second electrode provided on the second compound semiconductor layer,
an insulating layer that covers a side surface of the light-emitting device portion and a top peripheral portion of the second compound semiconductor layer and has an opening portion in which a top central portion of the second electrode is exposed,
an extraction electrode that is formed on the insulating layer so as to extend from the exposed top surface of the second electrode to the insulating layer, and
a first electrode that is electrically connected to the first compound semiconductor layer,
the extraction electrode is electrically connected to the second connection portion or forms the second connection portion,
the first electrode is electrically connected to the first connection portion or forms the first connection portion, and
a planar shape of the second compound semiconductor layer and a planar shape of the opening portion of the insulating layer are rectangular.
